(19) United States
(12) Patent Application Publication
(10) Pub. No.: US 2025/0167514 A1
(43) Pub. Date: May 22, 2025

(54) SURFACE-EMITTING LASER, LIGHT SOURCE DEVICE, AND ELECTRONIC DEVICE

(71) Applicant: SONY GROUP CORPORATION, Tokyo (JP)

(72) Inventors: Shuhei YAMAGUCHI, Kanagawa (JP); Hideki WATANABE, Kanagawa (JP); Rintaro KODA, Tokyo (JP); Yasutaka HIGA, Tokyo (JP); Gyongsok SONG, Kanagawa (JP); Tatsuya MATOU, Kanagawa (JP)

(21) Appl. No.: 18/840,373

(22) PCT Filed: Feb. 3, 2023
(86) PCT No.: PCT/JP2023/003526

§ 371 Date: Aug. 21, 2024

(30) Foreign Application Priority Data
Mar. 24, 2022 (JP) 2022-048190

(51) Int. Cl. H01S 5/042; H01S 5/183

(52) U.S. Cl. CPC H01S 5/04256; H01S 5/183

(57) ABSTRACT

The surface-emitting laser according to the present technique includes a first structure including a first reflector, a second structure including a second reflector, and an active layer disposed between the first and second structures. An electrode is provided within the first structure. According to the surface-emitting laser of the present technique, a surface-emitting laser capable of reducing series resistance without requiring the formation of a mesa can be provided.

### TECHNICAL FIELD

The technique according to the present disclosure (hereinafter also called “the present technique”) relates to a surface-emitting laser, a light source device, and an electronic device.

### BACKGROUND ART

A conventional surface-emitting laser is known in which a first electrode is provided on a rear surface of a substrate and a second electrode is provided on a front surface of a mesa-shaped upper reflector (see, for example, PTL 1).

### CITATION LIST

### Patent Literature

### [PTL 1]

JP 2009-164449A

### SUMMARY

### Technical Problem

However, in the conventional surface-emitting laser, there is room for improvement in reducing series resistance without requiring the formation of a mesa.

Accordingly, a main object of the present technique is to provide a surface-emitting laser capable of reducing series resistance without requiring the formation of a mesa.

### Solution to Problem

The present technique provides a surface-emitting laser including:
a first structure including a first reflector;
a second structure including a second reflector; and
an active layer disposed between the first and second structures, wherein an electrode is provided within the first structure.

The first structure may have an internal space, and the electrode may be provided within the internal space.

The electrode may be in contact with a wall surface of the internal space.

A current confinement region having at least one annular light-emitting region setting part that sets a light-emitting region of the active layer may be formed in the first structure and/or the second structure, and the internal space may have a surrounding part, in which the electrode is disposed, that surrounds a part of the first structure corresponding to a central part of the light-emitting region.

The electrode may include a plurality of electrode parts disposed at different positions in the surrounding part.

A wiring may further be included, the wiring being provided so as to penetrate the second structure, the active layer, and a part between the internal space of the first structure and the active layer, with one end of the wiring being connected to the electrode.

The penetrating part of the wiring may be surrounded by a high-resistance region or an insulating region.

An other end of the wiring may be disposed on a surface opposite from a surface of the second structure on which the active layer is located.

The at least one light-emitting region setting part may be a plurality of light-emitting region setting parts, and the internal space may have a plurality of the surrounding parts each corresponding to one of a plurality of the light-emitting regions.

The plurality of the electrodes provided in the plurality of the surrounding parts may be electrically connected to each other.

A low refractive index material may be provided in a region of the internal space that surrounds the electrode.

In the first structure, a first component part including at least a part of the first reflector and a second component part may be overlaid and bonded together, and a first junction surface that is a junction surface of one of the first and second component parts with the other of the first and second component parts may include a wall surface of the internal space.

The internal space may be defined by: a recess provided in a second junction surface that is a junction surface of the other of the first and second component parts with the one of the first and second component parts; and the first junction surface.

A cross-section of the surrounding part may have a shape that becomes thinner with proximity to a center.

The first structure may include a semiconductor layer having the wall surface on the active layer side.

An other electrode may be provided in a region surrounded by the light-emitting region setting part when seen in plan view, on a surface of the second structure opposite from the active layer side.

The other electrode may have a surrounding portion surrounding a center of the light-emitting region when seen in plan view.

The second structure may have a mesa including at least a part of the second reflector, and the other electrode may be located in a region of the second structure in a periphery of the mesa.

The present technique also provides a light source device including: the surface-emitting laser; and a laser driver that drives the surface-emitting laser, wherein the laser driver and the other end of the wiring are bonded by a conductive bump.

The present technique also provides an electronic device including the surface-emitting laser.

### BRIEF DESCRIPTION OF DRAWINGS

FIG. 1A is a cross-sectional view of a surface-emitting laser according to Example 1 of one embodiment of the present technique. FIG. 1B is a plan view of the surface-emitting laser according to Example 1 of one embodiment of the present technique.

FIG. 2 is a plan view of a first reflector and a cathode electrode of the surface-emitting laser according to Example 1 of one embodiment of the present technique.

FIG. 3 is a flowchart illustrating an example of a method for manufacturing the surface-emitting laser illustrated in FIG. 1.

FIG. 4A and FIG. 4B are cross-sectional views illustrating respective steps in the example of the method for manufacturing the surface-emitting laser illustrated in FIG. 1.

FIG. 5A and FIG. 5B are cross-sectional views illustrating respective steps in the example of the method for manufacturing the surface-emitting laser illustrated in FIG. 1.

FIG. 6A and FIG. 6B are cross-sectional views illustrating respective steps in the example of the method for manufacturing the surface-emitting laser illustrated in FIG. 1.

FIG. 7A and FIG. 7B are cross-sectional views illustrating respective steps in the example of the method for manufacturing the surface-emitting laser illustrated in FIG. 1.

FIG. 8A and FIG. 8B are cross-sectional views illustrating respective steps in the example of the method for manufacturing the surface-emitting laser illustrated in FIG. 1.

FIG. 9 is a cross-sectional view illustrating a step in the example of the method for manufacturing the surface-emitting laser illustrated in FIG. 1.

FIG. 10A is a cross-sectional view of a surface-emitting laser according to Example 2 of one embodiment of the present technique. FIG. 10B is a plan view of the surface-emitting laser according to Example 2 of one embodiment of the present technique.

FIG. 11 is a cross-sectional view of a surface-emitting laser according to Example 3 of one embodiment of the present technique.

FIG. 12 is a flowchart illustrating an example of a method for manufacturing the surface-emitting laser illustrated in FIG. 11.

FIG. 13A and FIG. 13B are cross-sectional views illustrating respective steps in the example of the method for manufacturing the surface-emitting laser illustrated in FIG. 11.

FIG. 14A to FIG. 14C are cross-sectional views illustrating respective steps in the example of the method for manufacturing the surface-emitting laser illustrated in FIG. 11.

FIG. 15A and FIG. 15B are cross-sectional views illustrating respective steps in the example of the method for manufacturing the surface-emitting laser illustrated in FIG. 11.

FIG. 16A and FIG. 16B are cross-sectional views illustrating respective steps in the example of the method for manufacturing the surface-emitting laser illustrated in FIG. 11.

FIG. 17A and FIG. 17B are cross-sectional views illustrating respective steps in the example of the method for manufacturing the surface-emitting laser illustrated in FIG. 11.

FIG. 18 is a cross-sectional view of a surface-emitting laser according to Example 4 of one embodiment of the present technique.

FIG. 19 is a cross-sectional view of a surface-emitting laser according to Example 5 of one embodiment of the present technique.

FIG. 20 is a cross-sectional view of a surface-emitting laser according to Example 6 of one embodiment of the present technique.

FIG. 21 is a cross-sectional view of a surface-emitting laser according to Example 7 of one embodiment of the present technique.

FIG. 22 is a cross-sectional view of a surface-emitting laser according to Example 8 of one embodiment of the present technique.

FIG. 23 is a cross-sectional view of a surface-emitting laser according to Example 9 of one embodiment of the present technique.

FIG. 24A is a cross-sectional view of a surface-emitting laser according to Example 10 of one embodiment of the present technique. FIG. 24B is a plan view of an anode electrode and a cathode electrode of the surface-emitting laser according to Example 10 of one embodiment of the present technique.

FIG. 25 is a cross-sectional view of a surface-emitting laser according to Example 11 of one embodiment of the present technique.

FIG. 26 is a cross-sectional view of a surface-emitting laser according to Example 12 of one embodiment of the present technique.

FIG. 27A to FIG. 27D are diagrams illustrating Variations 1 to 4, respectively, on an internal space of the surface-emitting laser according to one embodiment of the present technique.

FIG. 28 is a cross-sectional view of a light source device including the surface-emitting laser illustrated in FIG. 1.

FIG. 29 is a cross-sectional view of a light source device including the surface-emitting laser illustrated in FIG. 24.

FIG. 30 is a cross-sectional view of an example in which the surface-emitting laser according to Example 1 of one embodiment of the present technique is applied in a distance measurement device.

FIG. 31 is a block diagram illustrating an example of the overall configuration of a vehicle control system.

FIG. 32 is an explanatory diagram illustrating an example of an installation position of a distance measurement device.

### DESCRIPTION OF EMBODIMENTS

Hereinafter, preferred embodiments of the present technique will be described in detail with reference to the accompanying drawings. In the present specification and the drawings, components having substantially the same functional configuration will be denoted by the same reference signs, and thus repeated descriptions thereof will be omitted. The following embodiments describe representative embodiments of the present technique, and the scope of the present technique should not be narrowly interpreted on the basis thereof. Although the present specification will describe a surface-emitting laser, a light source device, and an electronic device according to the present technique as having a plurality of effects, it is sufficient for the surface-emitting laser, the light source device, and the electronic device according to the present technique to have at least one effect. The advantageous effects described in the present specification are merely exemplary and are not limited, and other advantageous effects may be obtained.

The descriptions will be given in the following order.
0. Introduction
1. Surface-Emitting Laser According to Example 1 of One Embodiment of Present Technique
2. Surface-Emitting Laser According to Example 2 of One Embodiment of Present Technique
3. Surface-Emitting Laser According to Example 3 of One Embodiment of Present Technique
4. Surface-Emitting Laser According to Example 4 of One Embodiment of Present Technique
5. Surface-Emitting Laser According to Example 5 of One Embodiment of Present Technique
6. Surface-Emitting Laser According to Example 6 of One Embodiment of Present Technique
7. Surface-Emitting Laser According to Example 7 of One Embodiment of Present Technique
8. Surface-Emitting Laser According to Example 8 of One Embodiment of Present Technique
9. Surface-Emitting Laser According to Example 9 of One Embodiment of Present Technique
10. Surface-Emitting Laser According to Example 10 of One Embodiment of Present Technique
11. Surface-Emitting Laser According to Example 11 of One Embodiment of Present Technique
12. Surface-Emitting Laser According to Example 12 of One Embodiment of Present Technique
13. Variations on Internal Space of Surface-Emitting Laser According to One Embodiment of Present Technique
14. Light Source Device Including Surface-Emitting Laser According to Example 1 of One Embodiment of Present Technique
15. Light Source Device Including Surface-Emitting Laser According to Example 10 of One Embodiment of Present Technique
16. Other Variations on Present Technique
17. Example of Application to Electronic Device
18. Example of Applying Surface-Emitting Laser to Distance Measurement Device
19. Example of Installing Distance Measurement Device on Moving Body

### <0. Introduction>

In vertical-cavity surface-emitting lasers (VCSELs), it is basically necessary to make contact with an anode electrode and a cathode electrode provided on either side of an active layer, for which forming a mesa is generally necessary. However, there have been problems with mesa formation, such as narrower pitches making manufacturing more difficult, an increase in the number of processes due to the need to protect the perimeter of the mesa to improve reliability, and the like. There has also been a problem in that the series resistance of the surface-emitting laser has increased depending on the arrangement of the electrodes.

Accordingly, after diligent investigations, the inventors developed the surface-emitting laser according to the present technique as a surface-emitting laser capable of reducing series resistance without requiring the formation of a mesa.

Several examples of surface-emitting lasers according to one embodiment of the present technique will be described in detail hereinafter.

### <1. Surface-Emitting Laser According to Example 1 of One Embodiment of Present Technique>

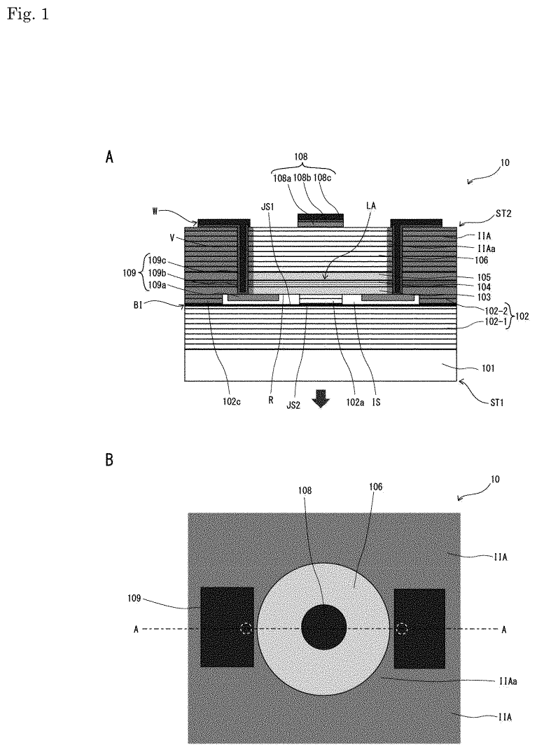

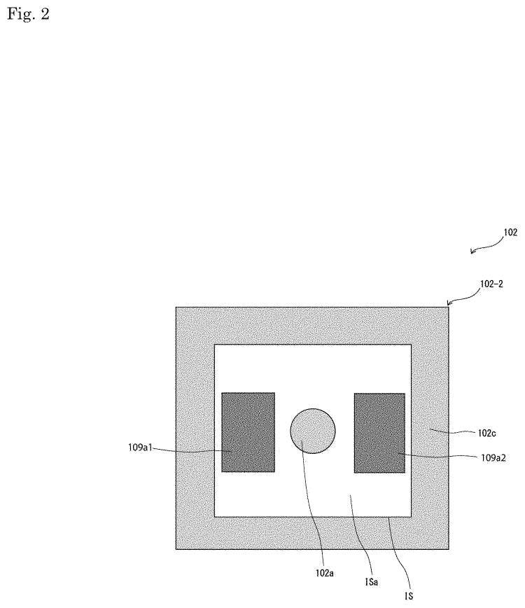

FIG. 1A is a cross-sectional view of a surface-emitting laser 10 according to Example 1 of one embodiment of the present technique. FIG. 1B is a plan view of the surface-emitting laser 10. FIG. 1A is a cross-sectional view taken along line A-A of FIG. 1B. FIG. 2 is a plan view of a first reflector 102 and a cathode electrode 109a of the surface-emitting laser 10. For the sake of convenience, the following will describe the upper part and the lower part in the cross-sectional view in FIG. 1 and the like as the “top” and the “bottom”, respectively.

### <<Configuration of Surface-Emitting Laser>>

### [Overall Configuration]

The surface-emitting laser 10 according to Example 1 is a vertical-cavity surface-emitting laser (VCSEL). As illustrated in FIGS. 1A and 1B, the surface-emitting laser 10 includes a first structure ST1 including the first reflector 102, a second structure ST2 including a second reflector 106, and an active layer 104 disposed between the first and second structures ST1 and ST2. A light-emitting unit (a resonator) is configured including the first and second reflectors 102 and 106 and the active layer 104. The surface-emitting laser 10 is driven by a laser driver, for example.

The first structure ST1 further includes a substrate 101 disposed on the side of the first reflector 102 opposite from the side on which the active layer 104 is located, and a first cladding layer 103 disposed between the first reflector 102 and the active layer 104. The cathode electrode 109a is provided inside the first structure ST1.

An ion implantation region IIA (a high-resistance region; the dark gray region in FIG. 1A and the like) is formed in the first structure ST1 and the second structure ST2 as a current confinement region, which has an annular light-emitting region setting part IIAa that sets a light-emitting region LA of the active layer 104. The light-emitting region setting part IIAa is, for example, a circular, polygonal, or similar frame shape when seen in plan view. The thickness of the ion implantation region IIA as the current confinement region is, for example, 10 to 8000 nm. For example, H+, B+, and the like can be given as examples of the ion species in the ion implantation region IIA. Here, the ion implantation region IIA is formed in an upper part of a peripheral region of the first structure ST1 and in the entirety, in the thickness direction, of a peripheral region of the second structure ST2, but the configuration is not limited thereto. The ion implantation region IIA may be formed in only a part (e.g., an upper part), in the thickness direction, of the peripheral region of the second structure ST2, or the ion implantation region IIA may also be formed in a lower part of the peripheral region of the first structure ST1. In addition to a function of suppressing the flow of current between adjacent surface-emitting lasers 10, the ion implantation region IIA functions as a current confinement region for the surface-emitting lasers 10, when the surface-emitting lasers 10 are arranged in an array, for example.

The second structure ST2 further includes a second cladding layer 105 disposed between the active layer 104 and the second reflector 106. An anode electrode 108 is provided in a region surrounded by the light-emitting region setting part IIAa when seen in plan view, on the surface of the second structure ST2 opposite from the active layer 104 side (for example, the upper surface of the second reflector 106).

For example, the surface-emitting laser 10 emits laser light from the rear surface (bottom surface) side of the substrate 101. In other words, the surface-emitting laser 10 is a rear-emitting VCSEL, for example.

### [First Structure]

### (Substrate)

The substrate 101 is formed from, for example, a semiconductor substrate (e.g., a GaAs substrate) of a first conductivity type (e.g., n type). A thin film that does not reflect or almost does not reflect light emitted by the surface-emitting laser 10 (light at an oscillation wavelength A from the surface-emitting laser 10) is formed on the rear surface (bottom surface) of the substrate 101 as an AR coating film. This thin film is generally constituted by a material that absorbs almost no light at the oscillation wavelength A.

### (First Cladding Layer)

The first cladding layer 103 is formed from, for example, an AlGaAs-based compound semiconductor of the first conductivity type (e.g., n type).

### (First Reflector, Internal Space, and Cathode Electrode)

The first reflector 102 is, for example, a semiconductor multilayer reflector. The multilayer reflector is also called a Distributed Bragg Reflector (DBR). The semiconductor multilayer reflector, which is a type of multilayer reflector (Distributed Bragg Reflector), has low light absorption and high reflectance, and is either conductive, semi-insulative, or insulative. Specifically, the first reflector 102 is, for example, a semiconductor multilayer reflector of the first conductivity type (e.g., n type), and has a structure in which a plurality of types (e.g., two types) of semiconductor layers having different refractive indices from each other are alternately layered at an optical thickness of ¼ of the oscillation wavelength. Each refractive index layer of the first reflector 102 is formed from an AlGaAs-based compound semiconductor of the first conductivity type (e.g., n type). The first reflector 102 is set to have a slightly lower reflectance than the second reflector 106. The first reflector 102 is also called a lower reflector.

As an example, in the first structure ST1, a first component part including a first part 102-1 that is a lower part of the first reflector 102 (also called a “first reflector lower part” hereinafter) and the substrate 101, and a second component part including a second part 102-2 that is an upper part of the first reflector 102 (also called a “first reflector upper part” hereinafter) and the first cladding layer 103, are bonded to each other such that the first and second parts 102-1 and 102-2 face each other. Reference sign BI in FIG. 1A indicates the bonding interface between the first and second component parts.

As an example, the first structure ST1 has an internal space IS, and the cathode electrode 109a is provided in the internal space IS. More specifically, the cathode electrode 109a is provided in contact with the bottom surface of the first cladding layer 103 (the semiconductor layer) (that is, the surface on the first reflector 102 side), which is, for example, a wall surface on the active layer 104 side of the internal space IS. Although provided in a part of the internal space IS as an example, the cathode electrode 109a may be provided throughout the entirety of the internal space IS.

As one example, the internal space IS is defined by: the first cladding layer 103; and the first and second parts 102-1 and 102-2 of the first reflector 102. Specifically, a junction surface JS1 of the first component part including the first reflector lower part with the second component part including the first reflector upper part includes a wall surface on the side of the internal space IS opposite from the side on which the active layer 104 is located. The internal space IS is defined by: the junction surface JS1; and a recess R, which has an open end at a junction surface JS2 of the second component part including the first reflector upper part with the first component part including the first reflector lower part, and takes, as a base surface, the surface of the first cladding layer 103 on the side opposite from the side where the active layer 104 is located (that is, the bottom surface).

As one example, the first part 102-1 of the first reflector 102 (the first reflector lower part) has a broad, flat shape. As one example, the second part 102-2 of the first reflector 102 (the first reflector upper part) has a substantially cylindrical central part 102a (light transmissive part) corresponding to the central part of the light-emitting region LA, and a square frame-shaped peripheral part 102c surrounding the central part 102a with the internal space IS located therebetween (see FIG. 2). The central part 102a is 0.5 to 300 μm in diameter, for example. The second part 102-2 (the first reflector upper part) is 1 to 2000 nm thick, for example. Note that the peripheral part 102c is not limited to a square frame shape, and may have, for example, a circular frame shape, an elliptical frame shape, a polygonal frame shape other than a square frame shape, or the like.

As one example, the internal space IS has a peripheral part ISa, in which the cathode electrode 109a is disposed, around the central part 102a of the first reflector upper part in the first structure ST1 (and specifically, in the second component part including the first reflector upper part) (see FIG. 2). The peripheral part ISa has a lower refractive index than the central part 102a, which makes it possible to confine light. The shape of the peripheral part ISa may be any shape that surrounds the central part 102a. As one example, at least the peripheral part ISa of the internal space IS is preferably an insulating layer constituted by air, SiO₂, SiN, SiON, AlN, or the like, or a layer having a different refractive index from the central part 102a, such as a conductive layer constituted by a metal or the like. Here, the internal space IS is, for example, an insulating layer constituted by air. Current confinement is also possible if at least the peripheral part ISa of the internal space IS is constituted by an insulating layer.

The cathode electrode 109a is constituted by, for example, a first contact metal. As one example, the cathode electrode 109a includes a plurality of (e.g., two) electrode parts 109a1 and 109a2 disposed at different positions in the peripheral part ISa (see FIG. 2). The first contact metal serving as the cathode electrode 109a has a layered structure in which, for example, a Ti layer, a Pt layer, and an Au layer are layered in that order from the first cladding layer 103 side (e.g., a three-layer structure). The Ti layer is 2 nm to 100 nm thick, for example. The Pt layer is 2 nm to 300 nm thick, for example. The Au layer is 100 nm to 500 nm thick, for example. The cathode electrode 109a is electrically connected to the cathode (negative terminal) of a laser driver, for example.

### (Wiring)

The surface-emitting laser 10 further includes wiring W, which is provided so as to penetrate the second structure ST2, the active layer 104, and a part between the internal space IS of the first structure ST1 and the active layer 104 (e.g., the first cladding layer 103), and which is connected at one end to the cathode electrode 109a. As one example, the wiring W is constituted by a first pad metal 109b and a first plating metal 109c. As one example, the wiring W extends along a direction in which a via V extends (e.g., in the layering direction) within the via V, which penetrates the second structure ST2, the active layer 104, and a part between the internal space IS of the first structure ST1 and the active layer 104 (e.g., the first cladding layer 103), with one end connected to the cathode electrode 109a, and the other end provided on the upper surface of the second reflector 106 (the side opposite from the side on which the active layer 104 is located). A cathode wiring system 109 is constituted by the wiring W (the first pad metal 109b and the first plating metal 109c) and the cathode electrode 109a (the first contact metal). The first pad metal 109b has a layered structure in which, for example, a Ti layer, a Pt layer, and an Au layer are layered in that order from the first contact metal side and the side surface side of the via V (e.g., a three-layer structure). The Ti layer is 2 nm to 100 nm thick, for example. The Pt layer is 2 nm to 300 nm thick, for example. The Au layer is 100 nm to 1000 nm thick, for example. The first plating metal 109c is constituted by an Au layer, for example. The Au layer is 1000 nm to 5000 nm thick, for example. If, for example, the first pad metal 109b can be prevented from breaking by forming the first pad metal 109b thickly, and if the resistance can be reduced, the first plating metal 109c need not be provided. Note that to form the wiring W in a penetrating form, a trench may be provided instead of the via V.

The penetrating part of the wiring W, i.e., the part of the wiring W that penetrates the second structure ST2, the active layer 104, and the part between the internal space IS of the first structure ST1 and the active layer 104 (e.g., the first cladding layer 103), is surrounded by the ion implantation region IIA, which is a high-resistance region. The other end of the wiring W (the part provided on the upper surface of the second reflector 106) can be an external connection terminal on the cathode side (e.g., the connection region of a flip-chip connection).

### [Active Layer]

The active layer 104 has a quantum well structure including, for example, a barrier layer constituted by a GaAs-based compound semiconductor (e.g., InGaAs), and a quantum well layer. The quantum well structure may be a single quantum well structure (QW structure) or a multiple quantum well structure (MQW structure). For example, in the active layer 104, the region surrounded by the light-emitting region setting part IIAa of the ion implantation region IIA is the light-emitting region LA when seen in plan view. The active layer 104 may have a plurality of QW structures or a plurality of MQW structures laminated through tunnel junctions.

### [Second Structure]

### (Second Cladding Layer)

The second cladding layer 105 is formed from, for example, an AlGaAs-based compound semiconductor of a second conductivity type (e.g., p type).

### (Second Reflector)

The second reflector 106 is, for example, a semiconductor multilayer reflector. Specifically, the second reflector 106 is, for example, a semiconductor multilayer reflector of the second conductivity type (e.g., p type), and has a structure in which a plurality of types (e.g., two types) of semiconductor layers having different refractive indices from each other are alternately layered at an optical thickness of ¼ of the oscillation wavelength. Each refractive index layer of the second reflector 106 is formed from an AlGaAs-based compound semiconductor of the second conductivity type (e.g., p type). The second reflector 106 is also called an upper reflector.

### (Anode Electrode)

As one example, the anode electrode 108 has a layered structure in which a second contact metal 108a, a second pad metal 108b, and a second plating metal 108c are layered in that order from the second reflector 106 side (e.g., a three-layer structure). The anode electrode 108 can be an external connection terminal on the anode side (e.g., the connection region of a flip-chip connection). Here, the anode electrode 108 has a substantially circular shape when seen in plan view, but may have another shape when seen in plan view, such as a substantially oval shape, a substantially polygonal shape, or the like. The anode electrode 108 is electrically connected to the anode (positive terminal) of the laser driver, for example.

As one example, the second contact metal 108a is provided in contact with a surface on the side of the second reflector 106 opposite from the side on which the active layer 104 is located (the upper surface). The second contact metal 108a has a layered structure in which, for example, a Ti layer, a Pt layer, and an Au layer are layered in that order from the second reflector 106 (e.g., a three-layer structure). The Ti layer is 2 nm to 100 nm thick, for example. The Pt layer is 2 nm to 300 nm thick, for example. The Au layer is 100 nm to 500 nm thick, for example.

The second pad metal 108b has a layered structure in which, for example, a Ti layer, a Pt layer, and an Au layer are layered in that order from the second contact metal 108a (e.g., a three-layer structure). The Ti layer is 2 nm to 100 nm thick, for example. The Pt layer is 2 nm to 300 nm thick, for example. The Au layer is 100 nm to 1000 nm thick, for example.

The second plating metal 108c is constituted by an Au layer, for example. The Au layer is 1000 nm to 5000 nm thick, for example. If, for example, the second pad metal 108b can be prevented from breaking by forming the second pad metal 108b thickly, and if the resistance can be reduced, the second plating metal 108c need not be provided.

### <<Operations of Surface-Emitting Laser>>

Operations of the surface-emitting laser 10 will be briefly described hereinafter. In the surface-emitting laser 10, for example, current supplied from the anode side of the laser driver and flowing in from the anode electrode 108 is injected into the active layer 104 through the second reflector 106 and the second cladding layer 105 in that order while being confined by the ion implantation region IIA. At this time, the active layer 104 emits light, and when the light travels back and forth between the first and second reflectors 102 and 106 while being amplified by the active layer 104 and confined to the central part 102a of the first reflector 102, and oscillation conditions are met, the light is emitted as laser light from the rear surface of the substrate 101. The current passing through the active layer 104 flows to the cathode electrode 109a through the first cladding layer 103, and flows from the cathode electrode 109a to the cathode side of the laser driver, for example.

### <<Method for Manufacturing Surface-Emitting Laser>>

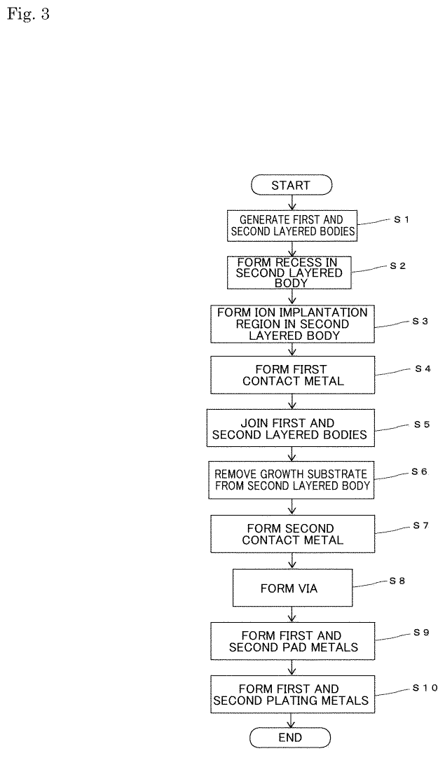

A method for manufacturing the surface-emitting laser 10 will be described hereinafter with reference to the flowchart in FIG. 3 and the like. Here, for example, a plurality of surface-emitting lasers 10 are produced simultaneously on a single wafer, which is the substrate 101, by a semiconductor manufacturing method using a semiconductor manufacturing device. The integrated plurality of surface-emitting lasers 10 are then separated from each other to obtain the plurality of surface-emitting lasers 10 in chip form.

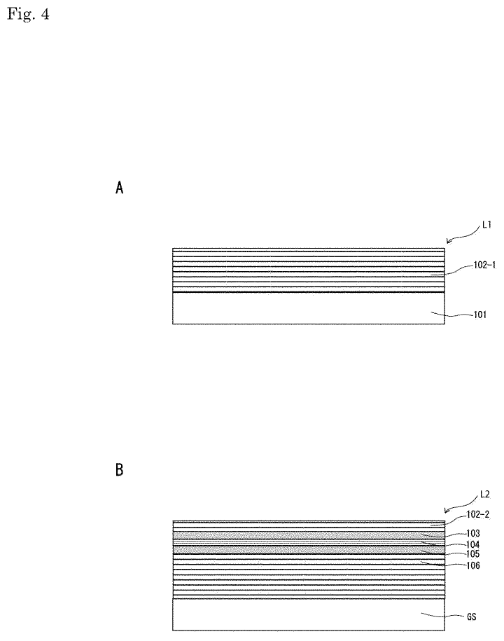

In the first step, step S1, first and second layered bodies L1 and L2 are produced (see FIG. 4A and FIG. 4B). The first part 102-1 of the first reflector 102 is layered on the substrate 101 through, for example, metalorganic chemical vapor deposition (MOCVD) (e.g., epitaxially grown at a growth temperature of 605° C.), to produce the first layered body L1. The second reflector 106, the second cladding layer 105, the active layer 104, the first cladding layer 103, and the second part 102-2 of the first reflector 102 are then layered on a growth substrate GS (e.g., a GaAs substrate) in that order through, for example, metalorganic chemical vapor deposition (MOCVD) (e.g., epitaxially grown at a growth temperature of 605° C.), to produce the second layered body L2. When performing MOCVD, trimethyl gallium ((CH₃)₃Ga) is used as the source gas for gallium, trimethyl aluminum ((CH₃)₃Al) is used as the source gas for aluminum, trimethyl indium ((CH₃)₃In) is used as the source gas for indium, and trimethyl hydrogen ((CH₃)₃As) is used as the source gas for As, for example. Monosilane (SiH₄) is used as the source gas for silicon, and carbon tetrabromide (CBr₄) is used as the source gas for carbon, for example.

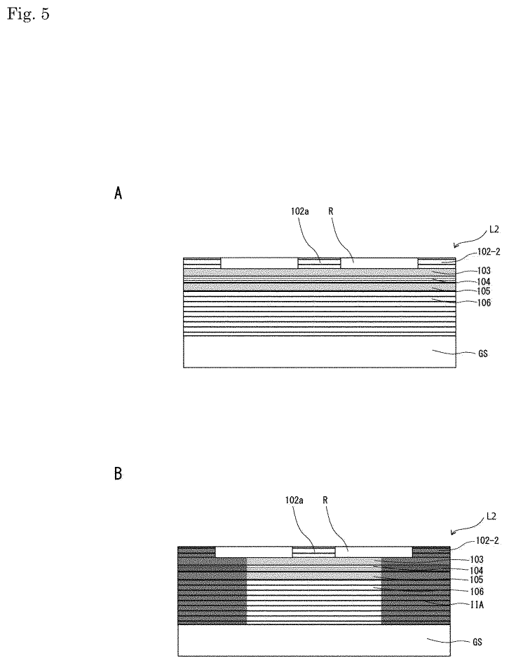

In the next step, step S2, the recess R is formed in the second layered body L2 (see FIG. 5A). Specifically, a resist pattern having an opening at the location of the second layered body L2 where the recess R is to be formed is formed through photolithography, and the resist pattern is used as a mask to etch the second part 102-2 of the first reflector 102 through, for example, reactive ion etching (RIE etching) or wet etching, which forms the recess R in the periphery of the central part 102a of the first reflector upper part. The etching at this time is performed to a depth that exposes the first cladding layer 103. The resist pattern is then removed.

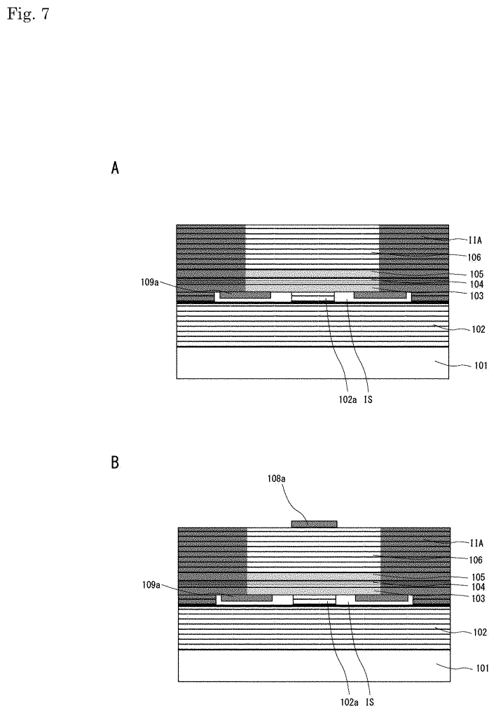

In step S3, the ion implantation region IIA is formed in the second layered body L2 (see FIG. 5B). Specifically, a resist pattern covering a region (a central region) of the second layered body L2 aside from the region where the ion implantation region IIA is to be formed (a peripheral region) is formed through photolithography, and ion implantation is performed from the second part 102-2 side using the resist pattern as a mask. At this time, the ions are implanted to a depth that reaches at least the growth substrate GS (until the bottom surface of the second reflector 106 is reached, in the state indicated in FIG. 5B). It should be noted that the ion implantation may also be performed on the first part 102-1 of the first reflector 102 of the first layered body L1 to form the ion implantation region IIA. If the ion implantation is performed from the first part 102-1 or the second part 102-2, and the injection is not deep enough to reach the growth substrate GS, the ion implantation may be performed again from the upper surface of the second reflector 106 in the state indicated in FIG. 7A, for example, after the growth substrate GS has been removed (step S6).

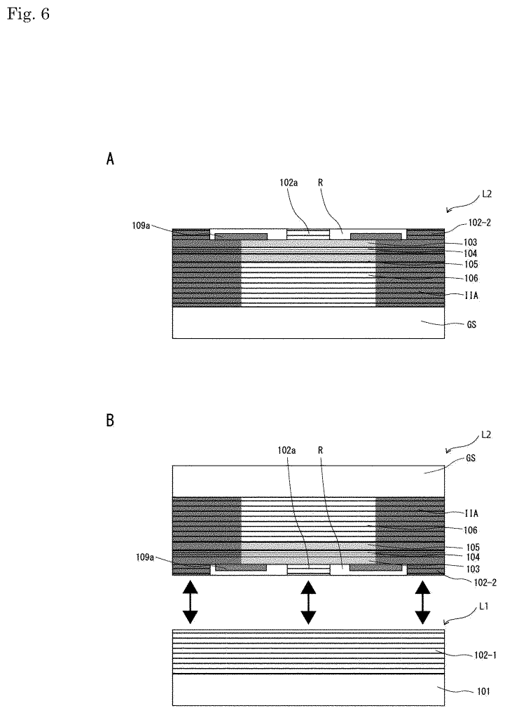

In the next step, step S4, the first contact metal is formed as the cathode electrode 109a (see FIG. 6A). Specifically, the plurality of electrode parts 109a1 and 109a2 of the cathode electrode 109a are formed on the base surface of the recess R in the second layered body L2 (the surface of the first cladding layer 103 opposite from the side on which the active layer 104 is located), through lift-off, for example (see FIG. 2). The first contact metal is deposited through vacuum deposition, sputtering, or the like, for example.

In the next step, step S5, the first and second layered bodies L1 and L2 are bonded (see FIG. 6B). Specifically, the first part 102-1 of the first reflector 102 of the first layered body L1 and the second part 102-2 of the first reflector 102 of the second layered body L2 are bonded facing each other. This completes the first reflector 102. Hereinafter, the result of bonding the first and second layered bodies L1 and L2 will be called simply a “layered body”.

In the next step, step S6, the growth substrate GS is removed from the second layered body L2 (see FIG. 7A). Specifically, after the growth substrate GS is polished and thinned, the thin film part is removed through wet etching. This exposes the second reflector 106.

In the next step, step S7, the second contact metal 108a is formed (see FIG. 7B). Specifically, the second contact metal 108a is formed on the exposed second reflector 106 of the layered body through lift-off, for example. The second contact metal 108a is deposited through vacuum deposition, sputtering, or the like, for example.

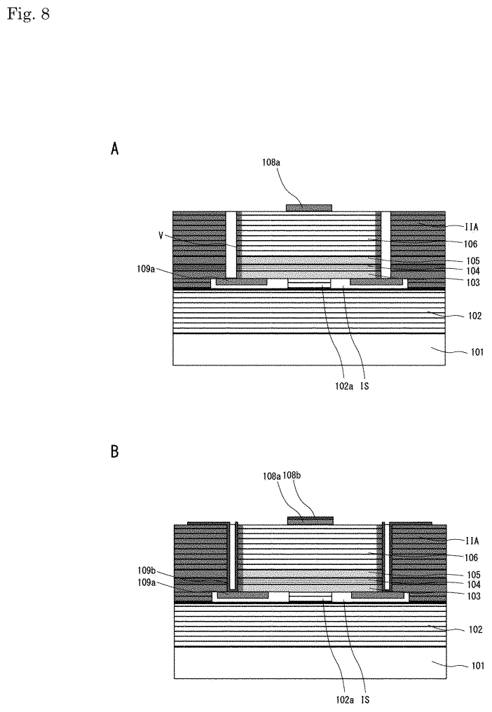

In the next step, step S8, the via V is formed (see FIG. 8A). Specifically, a resist pattern having an opening is formed at the location of the layered body where the via V is to be formed through photolithography, and using the resist pattern as a mask, the layered body is etched through RIE etching, for example, to form the via V. The etching at this time is performed to a depth that exposes the first contact metal as the cathode electrode 109a.

In the next step, step S9, the first and second pad metals 109b and 108b are formed (see FIG. 8B). Specifically, the first pad metal 109b is formed on the first contact metal, the side surfaces of the via V, and the second reflector 106, and the second pad metal 108b is formed on the second contact metal 108a, through lift-off, for example. The first and second pad metals 109b and 108b are deposited through vacuum deposition, sputtering, or the like, for example.

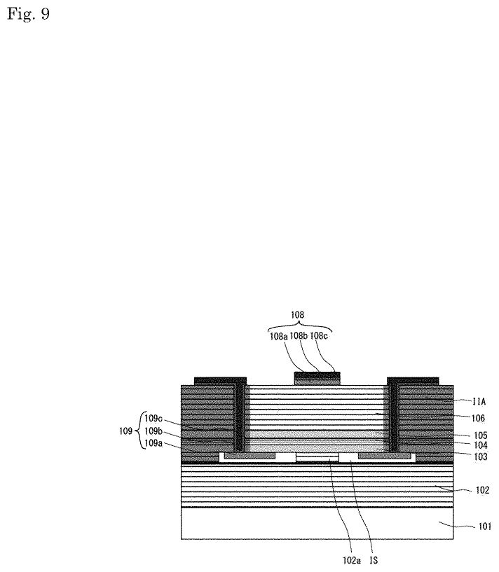

In the final step, step S10, the first and second plating metals 109c and 108c are formed (see FIG. 9). Specifically, the first plating metal 109c is formed on the first pad metal 109b, and the second plating metal 108c is formed on the second pad metal 108b, through plating, for example.

### <<Effects of Surface-Emitting Laser>>

Effects of the surface-emitting laser 10 will be described hereinafter. The surface-emitting laser 10 according to Example 1 of one embodiment of the present technique includes the first structure ST1 including the first reflector 102, the second structure ST2 including the second reflector 106, and the active layer 104 disposed between the first and second structures ST1 and ST2, and the cathode electrode 109a is provided within the first structure ST1. According to the surface-emitting laser 10, the cathode electrode 109a is provided within the first structure ST1, and thus a surface-emitting laser capable of reducing series resistance without requiring the formation of a mesa can be provided.

On the other hand, with the surface-emitting laser disclosed in PTL 1, for example, a first electrode is provided on a rear surface of a substrate, and a second electrode is provided on a front surface of a mesa-shaped upper reflector. It has therefore been necessary to form a mesa, and there has also been room for improvement in terms of reducing series resistance.

The first structure ST1 has the internal space IS, and the cathode electrode 109a is provided in the internal space IS. This makes it possible to accommodate the cathode electrode 109a within the internal space IS.

The cathode electrode 109a is in contact with a wall surface of the internal space IS. This makes it possible to electrically connect the cathode electrode 109a to the first structure ST1.

The cathode electrode 109a is in contact with a wall surface of the internal space IS on the active layer 104 side. This makes it possible to further reduce series resistance.

The ion implantation region IIA is formed in the first structure ST1 and/or the second structure as a current confinement region having at least one annular light-emitting region setting part IIAa that sets the light-emitting region LA of the active layer 104, and the internal space IS has a peripheral part ISa, in which the cathode electrode 109a is disposed, around the part of the first structure ST1 corresponding to the central part of the light-emitting region LA (the central part 102a of the second part 102-2). Through this, the current confinement diameter of the current confinement region can be defined by the peripheral part ISa. Furthermore, a light confinement effect can also be achieved due to a difference in the refractive indices of the central part 102a and the peripheral part ISa.

The cathode electrode 109a may include the plurality of electrode parts 109a1 and 109a2 disposed at different positions in the peripheral part ISa. In this case, the area of the cathode electrode 109a can be increased, and the resistance of the cathode electrode 109a can be lowered.

The wiring W, which is provided so as to penetrate the second structure ST2, the active layer 104, and a part between the internal space IS of the first structure ST1 and the active layer 104, and which is connected at one end to the cathode electrode 109a, is further provided. This makes it possible to direct the current flowing into the cathode electrode 109a to the side opposite from the active layer 104 side of the second structure ST2 through the wiring W.

The penetrating part of the wiring W is surrounded by the ion implantation region IIA, which is a high-resistance region. This makes it possible to suppress current flow between: the second structure ST2 and the active layer 104; and the wiring W.

The other end of the wiring W is located on a surface opposite from the surface of the second structure ST2 on which the active layer 104 is located. This makes it possible to use the other end as an external connection terminal.

A low refractive index material may be provided in the region of the internal space IS around the cathode electrode 109a. In this case, a light confinement effect based on the refractive index of the low refractive index material can be achieved.

In the first structure ST1, the first component part including at least a part of the first reflector 102 (the first reflector lower part) and the second component part including the first reflector upper part are overlaid and bonded, and the junction surface JS1, which is the junction surface of the first component part with the second component part, includes a wall surface on the side of the internal space IS opposite from the side on which the active layer 104 is located. As a result, the internal space IS can be formed by forming the recess R on the first reflector upper part side of the first structure ST1 and covering the recess with the junction surface JS1, which makes it easy to form the internal space IS.

The internal space IS is defined by the recess R provided in the junction surface JS2, which is the junction surface of the second component part with the first component part, and the junction surface JS1. This makes it possible to simplify the configuration of the internal space IS.

The first structure ST1 may include the first cladding layer 103 as a semiconductor layer having a wall surface on the active layer 104 side of the internal space IS. This makes it possible for current to flow through the active layer 104 to the cathode electrode 109a efficiently.

The anode electrode 108 may be provided in a region surrounded by the light-emitting region setting part IIAa when seen in plan view, on the surface of the second structure ST2 opposite from the active layer side. This makes it possible for current to flow through the active layer 104 efficiently.

Incidentally, VCSELs are used in a wide range of fields such as direct retinal imaging devices and facial recognition sensors, but there is a need for even higher efficiency and high yields during production. To achieve VCSELs that are highly efficient and provide good yields, it is necessary to fabricate the VCSELs having a confinement diameter in the confinement structure that, among current and light, confines at least light with high accuracy and good controllability, and further simplify the fabrication process. Currently, in AlGaAs-based VCSELs, an oxidation confinement layer that turns AlAs into AlOx through water vapor oxidation is mainly used. However, there is a problem in that the rate of water vapor oxidation varies over the wafer surface from batch to batch, which worsens the yield. In addition, it is basically necessary to ensure the anode electrode and the cathode electrode are in contact with the active layer therebetween, for which forming a mesa is generally necessary. However, there is a problem in that manufacturing becomes more difficult as the mesa becomes narrower, it is necessary to protect the perimeter of the mesa to improve reliability, and the like, which complicates the manufacturing process.

In the surface-emitting laser 10, the cathode electrode 109a is provided internally, which eliminates the need to form a mesa and makes it possible to simplify the manufacturing process. Furthermore, the surface-emitting laser 10 makes it possible to fabricate a confinement structure that, among light and current, confines at least light, with good controllability, which makes it possible to realize ultra-narrow-pitch VCSELs that have been difficult to fabricate conventionally.

### <2. Surface-Emitting Laser According to Example 2 of One Embodiment of Present Technique>

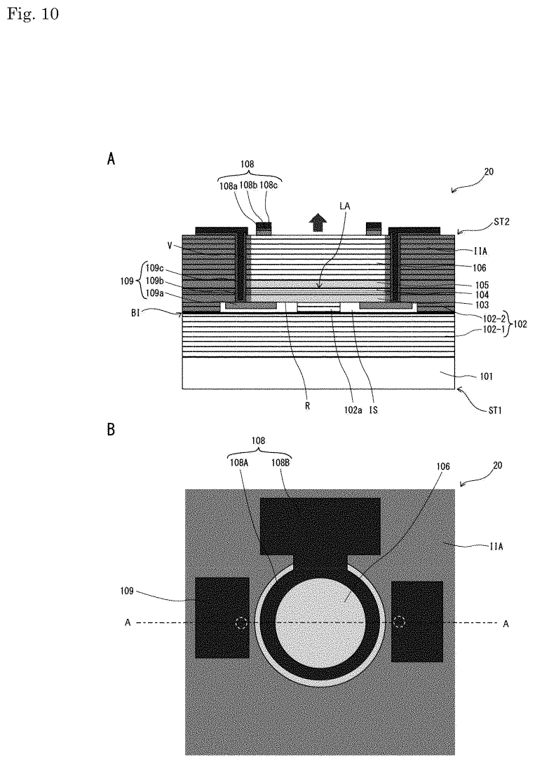

FIG. 10A is a cross-sectional view of a surface-emitting laser 20 according to Example 2 of one embodiment of the present technique. FIG. 10B is a plan view of the surface-emitting laser 20. FIG. 10A is a cross-sectional view taken along line A-A of FIG. 10B.

### <<Configuration of Surface-Emitting Laser>>

As illustrated in FIG. 10A and FIG. 10B, the surface-emitting laser 20 according to Example 2 has generally the same configuration as the surface-emitting laser 10 according to Example 1, except that the anode electrode 108 has a surrounding portion 108A, which surrounds the center of the light-emitting region LA of the active layer 104 when seen in plan view, and an external connection terminal part 108B. The surface-emitting laser 20 is a front surface-emitting type of surface-emitting laser in which the second reflector 106 is the reflector on the emitting side, and the inner side of the surrounding portion 108A of the anode electrode 108 is an emission aperture. The external connection terminal part 108B can be an external connection terminal on the anode side (e.g., the connection region of a flip-chip connection).

### <<Operations of Surface-Emitting Laser>>

Aside from emitting light from the second reflector 106, the surface-emitting laser 20 performs the same operations as the surface-emitting laser 10 according to Example 1.

### <<Method for Manufacturing Surface-Emitting Laser>>

The surface-emitting laser 20 can be manufactured through generally the same method as the method for manufacturing the surface-emitting laser 10 according to Example 1.

### <<Effects of Surface-Emitting Laser>>

According to the surface-emitting laser 20, the same effects as the surface-emitting laser 10 according to Example 1 can be achieved.

### <3. Surface-Emitting Laser According to Example 3 of One Embodiment of Present Technique>

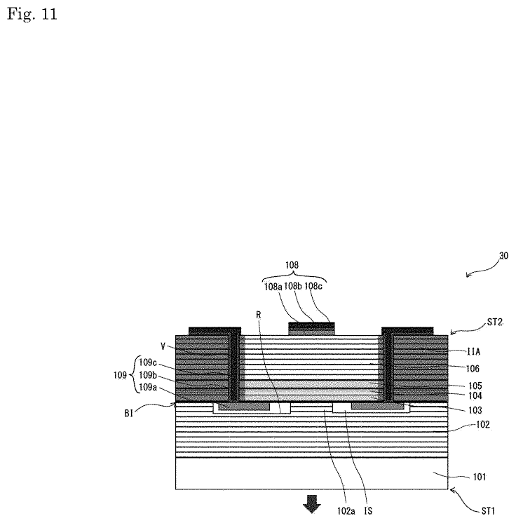

FIG. 11 is a cross-sectional view of a surface-emitting laser 30 according to Example 3 of one embodiment of the present technique.

### <<Configuration of Surface-Emitting Laser>>

As illustrated in FIG. 11, the surface-emitting laser 30 according to Example 3 has generally the same configuration as the surface-emitting laser 10 according to Example 1, except that a bonding interface BI is present between the first reflector 102 and the first cladding layer 103, i.e., the first reflector 102 and the first cladding layer 103 are bonded.

In the surface-emitting laser 30, the internal space IS is defined by the recess R provided in the active layer 104 side of the first reflector 102 (the upper surface) and the surface on the side of the first cladding layer 103 opposite from the side on which the active layer 104 is located (the bottom surface). In the surface-emitting laser 30, the cathode electrode 109a is provided on the bottom surface of the first cladding layer 103 (the surface opposite from the side on which the active layer 104 is located). The thickness of the cathode electrode 109a is preferably no greater than the depth of the recess R.

### <<Operations of Surface-Emitting Laser>>

The surface-emitting laser 30 performs the same operations as the surface-emitting laser 10 according to Example 1.

### <<Method for Manufacturing Surface-Emitting Laser>>

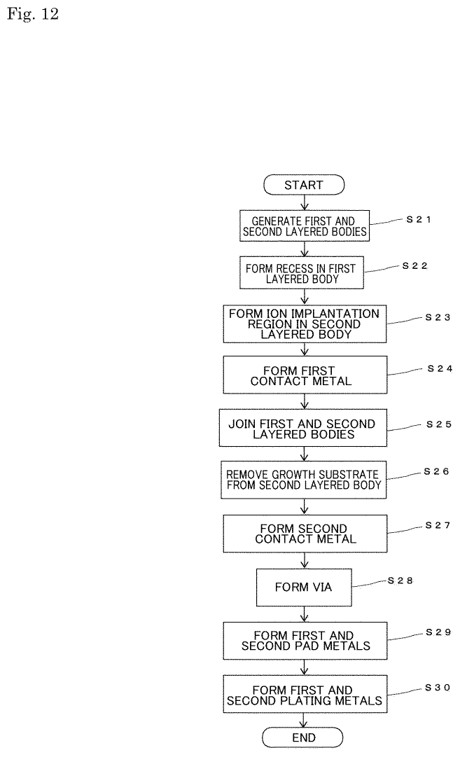

A method for manufacturing the surface-emitting laser 30 will be described hereinafter with reference to the flowchart in FIG. 12 and the like. Here, for example, a plurality of surface-emitting lasers 30 are produced simultaneously on a single wafer, which is the substrate 101, by a semiconductor manufacturing method using a semiconductor manufacturing device. The integrated plurality of surface-emitting lasers 30 are then separated from each other to obtain the plurality of surface-emitting lasers 30 in chip form.

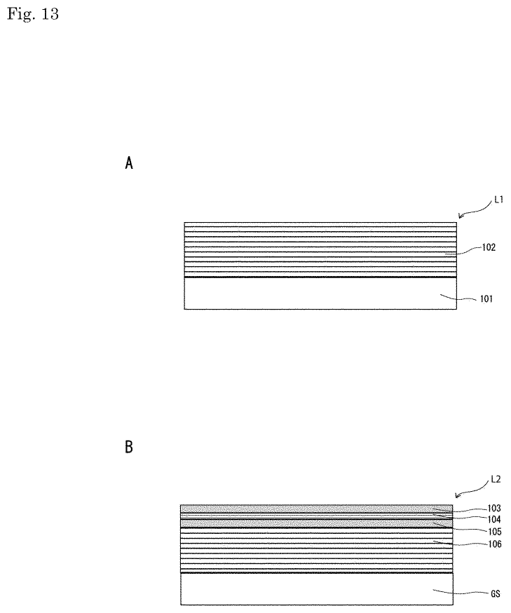

In the first step, step S21, first and second layered bodies L1 and L2 are produced (see FIG. 13A and FIG. 13B). The first reflector 102 is layered on the substrate 101 through, for example, metalorganic chemical vapor deposition (MOCVD) (e.g., epitaxially grown at a growth temperature of 605° C.), to produce the first layered body L1. The second reflector 106, the second cladding layer 105, the active layer 104, and the first cladding layer 103 are then layered on a growth substrate GS (e.g., a GaAs substrate) in that order through, for example, metalorganic chemical vapor deposition (MOCVD) (e.g., epitaxially grown at a growth temperature of 605° C.), to produce the second layered body L2. When performing MOCVD, trimethyl gallium ((CH₃)₃Ga) is used as the source gas for gallium, trimethyl aluminum ((CH₃)₃Al) is used as the source gas for aluminum, trimethyl indium ((CH₃)₃In) is used as the source gas for indium, and trimethyl hydrogen ((CH₃)₃As) is used as the source gas for As, for example. Monosilane (SiH₄) is used as the source gas for silicon, and carbon tetrabromide (CBr₄) is used as the source gas for carbon, for example.

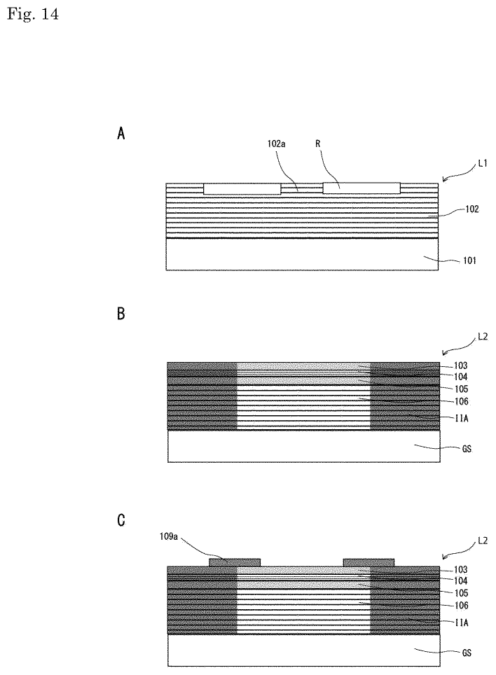

In the next step, step S22, the recess R is formed in the first layered body L1 (see FIG. 14A). Specifically, a resist pattern having an opening at the location of the first layered body L1 (and specifically, the first reflector 102) where the recess R is to be formed is formed through photolithography, and the resist pattern is used as a mask to etch the first reflector 102 through, for example, reactive ion etching (RIE etching) or wet etching, which forms the recess R in the periphery of the central part 102a of the first reflector 102. The resist pattern is then removed.

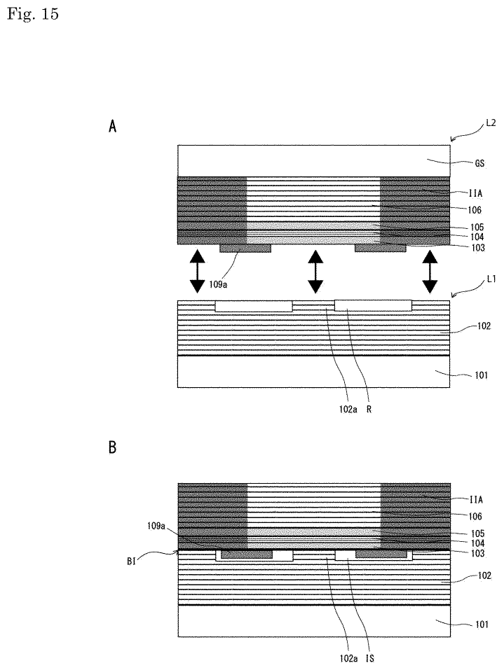

In the next step, step S23, the ion implantation region IIA is formed in the second layered body L2 (see FIG. 14B). Specifically, a resist pattern covering a region (a central region) of the second layered body L2 aside from the region where the ion implantation region IIA is to be formed (a peripheral region) is formed through photolithography, and ion implantation is performed from the first cladding layer 103 side using the resist pattern as a mask. At this time, the ions are implanted to a depth that reaches at least the growth substrate GS. It should be noted that the ion implantation may also be performed on the first reflector 102 of the first layered body L1 to form the ion implantation region IIA. If the ion implantation is performed from the first reflector 102 or the first cladding layer 103, and the injection is not deep enough to reach the growth substrate GS, the ion implantation may be performed again from the upper surface of the second reflector 106 in the state indicated in FIG. 15B, for example, after the growth substrate GS has been removed (step S26).

In the next step, step S24, the first contact metal is formed as the cathode electrode 109a (see FIG. 14C). Specifically, the cathode electrode 109a is formed at a position, in the first cladding layer 103 side surface of the second layered body L2, corresponding to the recess R formed in the first layered body L1, through lift off, for example. The thickness of the cathode electrode 109a at this time is no greater than the depth of the recess R. The first contact metal serving as the cathode electrode 109a is deposited through vacuum deposition, sputtering, or the like, for example.

In the next step, step S25, the first and second layered bodies L1 and L2 are bonded (see FIG. 15A). Specifically, the first reflector 102 of the first layered body L1 and the first cladding layer 103 of the second layered body L2 are bonded facing each other. At this time, the bonding is performed such that the cathode electrode 109a is accommodated within the recess R. Hereinafter, the result of bonding the first and second layered bodies L1 and L2 will be called simply a “layered body”.

In the next step, step S26, the growth substrate GS is removed from the second layered body L2 (see FIG. 15B). Specifically, after the growth substrate GS is polished and thinned, the thin film part is removed through wet etching. This exposes the second reflector 106.

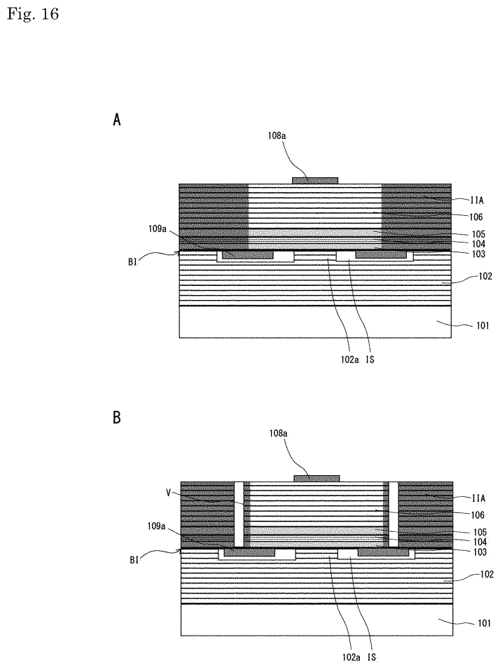

In the next step, step S27, the second contact metal 108a is formed (see FIG. 16A). Specifically, the second contact metal 108a is formed on the exposed second reflector 106 of the layered body through lift-off, for example. The second contact metal 108a is deposited through vacuum deposition, sputtering, or the like, for example.

In the next step, step S28, the via V is formed (see FIG. 16B). Specifically, a resist pattern having an opening is formed at the location of the layered body where the via V is to be formed through photolithography, and using the resist pattern as a mask, the layered body is etched through RIE etching, for example, to form the via V. The etching at this time is performed to a depth that exposes the first contact metal as the cathode electrode 109a (to a depth at which the second reflector 106 is penetrated).

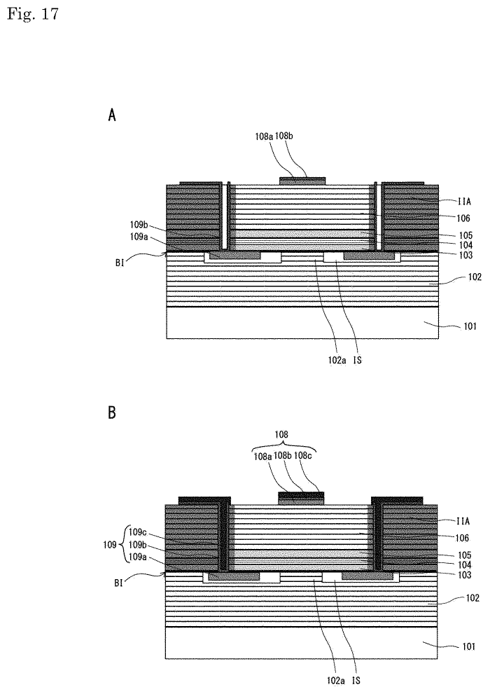

In the next step, step S29, the first and second pad metals 109b and 108b are formed (see FIG. 17A). Specifically, the first pad metal 109b is formed on the first contact metal, the side surfaces of the via V, and the second reflector 106, and the second pad metal 108b is formed on the second contact metal 108a, through lift-off, for example. The first and second pad metals 109b and 108b are deposited through vacuum deposition, sputtering, or the like, for example.

In the final step, step S30, the first and second plating metals 109c and 108c are formed (see FIG. 17B). Specifically, the first plating metal 109c is formed on the first pad metal 109b, and the second plating metal 108c is formed on the second pad metal 108b, through plating, for example.

### <<Effects of Surface-Emitting Laser>>

According to the surface-emitting laser 30, the same effects as the surface-emitting laser 10 according to Example 1 can be achieved.

### <4. Surface-Emitting Laser According to Example 4 of One Embodiment of Present Technique>

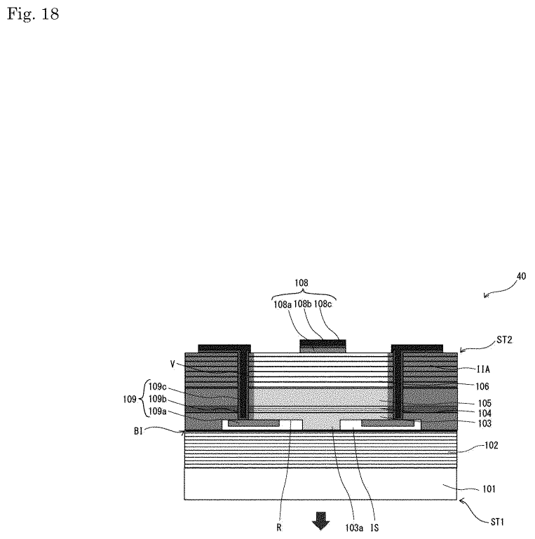

FIG. 18 is a cross-sectional view of a surface-emitting laser 40 according to Example 4 of one embodiment of the present technique.

### <<Configuration of Surface-Emitting Laser>>

As illustrated in FIG. 18, the surface-emitting laser 40 according to Example 4 has generally the same configuration as the surface-emitting laser 10 according to Example 1, except that the first reflector 102 and the first cladding layer 103 are bonded, and the internal space IS is defined by the recess R formed in the junction surface of the first cladding layer 103 with the first reflector 102 and the junction surface of the first reflector 102 with the first cladding layer 103. In the surface-emitting laser 40, the recess R is formed around a central part 103a of the first cladding layer 103.

### <<Operations of Surface-Emitting Laser>>

The surface-emitting laser 40 performs the same operations as the surface-emitting laser 10 according to Example 1.

### <<Method for Manufacturing Surface-Emitting Laser>>

The surface-emitting laser 40 can be manufactured through a manufacturing method based on the method for manufacturing the surface-emitting laser 10 according to Example 1.

### <<Effects of Surface-Emitting Laser>>

According to the surface-emitting laser 40, the same effects as the surface-emitting laser 10 according to Example 1 can be achieved.

### <5. Surface-Emitting Laser According to Example 5 of One Embodiment of Present Technique>

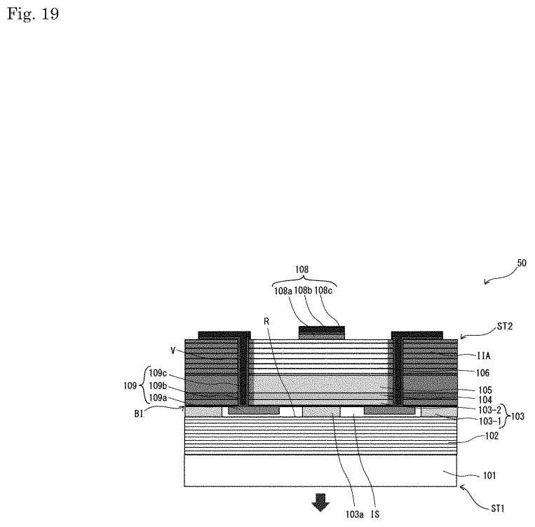

FIG. 19 is a cross-sectional view of a surface-emitting laser 50 according to Example 5 of one embodiment of the present technique.

### <<Configuration of Surface-Emitting Laser>>

As illustrated in FIG. 19, the surface-emitting laser 50 according to Example 5 has generally the same configuration as the surface-emitting laser 30 according to Example 3, except that the bonding interface BI is present within the first cladding layer 103.

In the surface-emitting laser 50, in the first structure ST1, the first component part, which includes the first reflector 102 and a first part 103-1 that is a lower part of the first cladding layer 103 (also called a “first cladding layer lower part” hereinafter), and the second component part, which is constituted by a second part 103-2 that is an upper part of the first cladding layer 103 (also called a “second cladding layer upper part” hereinafter), are bonded together with the first and second parts 103-1 and 103-2 facing each other. The internal space IS is defined by: the recess R, which has an open end at the junction surface between the first component part including the first cladding layer lower part and the second component part including the second cladding layer upper part, and which takes the active layer 104 side surface of the first reflector 102 (the upper surface) as a base surface; and the junction surface of the second component part including a first cladding layer upper part with the first component part including the first cladding layer lower part. In the surface-emitting laser 50, the recess R is formed around a central part 103a of the first cladding layer 103. In the surface-emitting laser 50, the cathode electrode 109a is provided on the bottom surface of the first cladding layer upper part (the surface opposite from the side on which the active layer 104 is located). The thickness of the cathode electrode 109a is preferably no greater than the depth of the recess R.

### <<Operations of Surface-Emitting Laser>>

The surface-emitting laser 50 performs the same operations as the surface-emitting laser 10 according to Example 1.

### <<Method for Manufacturing Surface-Emitting Laser>>

The surface-emitting laser 50 can be manufactured through a manufacturing method based on the method for manufacturing the surface-emitting laser 30 according to Example 3.

### <<Effects of Surface-Emitting Laser>>

According to the surface-emitting laser 50, the same effects as the surface-emitting laser 30 according to Example 3 can be achieved.

### <6. Surface-Emitting Laser According to Example 6 of One Embodiment of Present Technique>

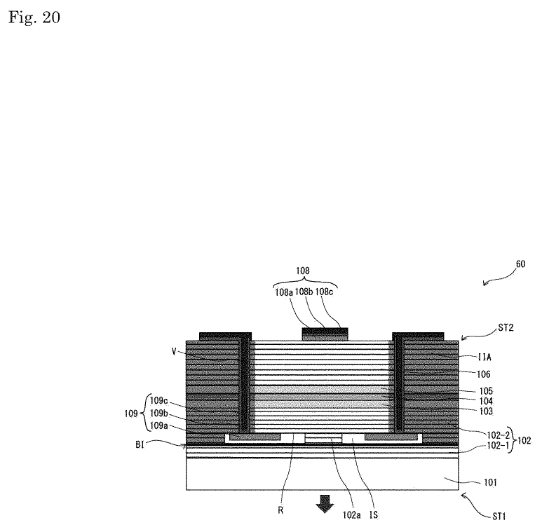

FIG. 20 is a cross-sectional view of a surface-emitting laser 60 according to Example 6 of one embodiment of the present technique.

### <<Configuration of Surface-Emitting Laser>>

As illustrated in FIG. 20, the surface-emitting laser 60 according to Example 6 has generally the same configuration as the surface-emitting laser 10 according to Example 1, except that the internal space IS is defined by: the recess R provided in the junction surface of the second component part including the first reflector upper part with the first component part including the first reflector lower part; and the junction surface of the first component part including the first reflector lower part and the second component part including the first reflector upper part.

### <<Operations of Surface-Emitting Laser>>

The surface-emitting laser 60 performs the same operations as the surface-emitting laser 10 according to Example 1.

### <<Method for Manufacturing Surface-Emitting Laser>>

The surface-emitting laser 60 can be manufactured through a manufacturing method based on the method for manufacturing the surface-emitting laser 10 according to Example 1.

### <<Effects of Surface-Emitting Laser>>

According to the surface-emitting laser 60, the same effects as the surface-emitting laser 10 according to Example 1 can be achieved.

### <7. Surface-Emitting Laser According to Example 7 of One Embodiment of Present Technique>

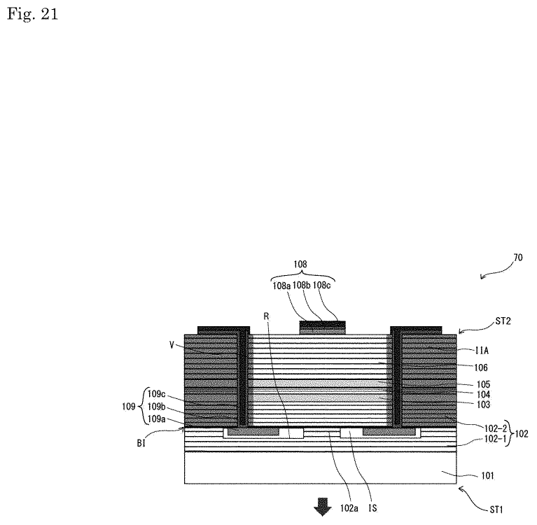

FIG. 21 is a cross-sectional view of a surface-emitting laser 70 according to Example 7 of one embodiment of the present technique.

### <<Configuration of Surface-Emitting Laser>>

As illustrated in FIG. 21, the surface-emitting laser 70 according to Example 7 has generally the same configuration as the surface-emitting laser 30 according to Example 3, except that the internal space IS is defined by: the recess R provided in the junction surface of the first component part including the first reflector lower part with the second component part including the first reflector upper part; and the junction surface of the second component part including the first reflector upper part and the first component part including the first reflector lower part. In the surface-emitting laser 70, the cathode electrode 109a is provided on the bottom surface of the first reflector upper part (the surface opposite from the side on which the active layer 104 is located). The thickness of the cathode electrode 109a is preferably no greater than the depth of the recess R.

### <<Operations of Surface-Emitting Laser>>

The surface-emitting laser 70 performs the same operations as the surface-emitting laser 10 according to Example 1.

### <<Method for Manufacturing Surface-Emitting Laser>>

The surface-emitting laser 70 can be manufactured through a manufacturing method based on the method for manufacturing the surface-emitting laser 30 according to Example 3.

### <<Effects of Surface-Emitting Laser>>

According to the surface-emitting laser 70, the same effects as the surface-emitting laser 30 according to Example 3 can be achieved.

### <8. Surface-Emitting Laser According to Example 8 of One Embodiment of Present Technique>

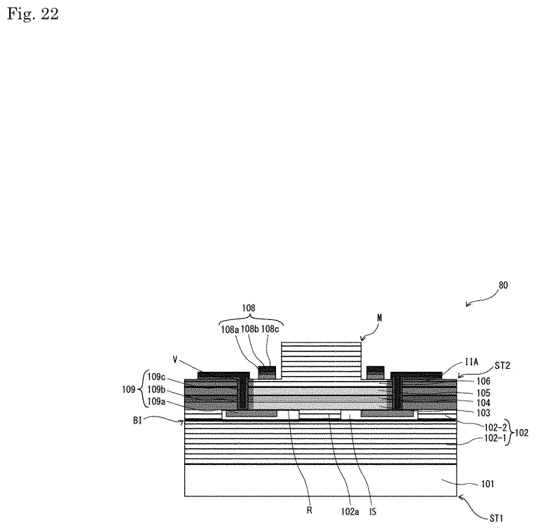

FIG. 22 is a cross-sectional view of a surface-emitting laser 80 according to Example 8 of one embodiment of the present technique.

### <<Configuration of Surface-Emitting Laser>>

As illustrated in FIG. 22, the surface-emitting laser 80 according to Example 8 has generally the same configuration as the surface-emitting laser 10 according to Example 1, except for having a double intra-cavity structure.

In the surface-emitting laser 80, the second structure ST2 has a mesa M including at least a part of the second reflector 106 (e.g., a part excluding the lower part), and the anode electrode 108 is disposed on a region of the second structure ST2 around the mesa M.

### <<Operations of Surface-Emitting Laser>>

The surface-emitting laser 80 performs generally the same operations as the surface-emitting laser 10 according to Example 1.

### <<Method for Manufacturing Surface-Emitting Laser>>

The surface-emitting laser 80 can be manufactured through a manufacturing method based on the method for manufacturing the surface-emitting laser 10 according to Example 1.

### <<Effects of Surface-Emitting Laser>>

According to the surface-emitting laser 80, the same effects as the surface-emitting laser 10 according to Example 1 can be achieved, and the series resistance can be further reduced by having the double intra-cavity structure.

### <9. Surface-Emitting Laser According to Example 9 of One Embodiment of Present Technique>

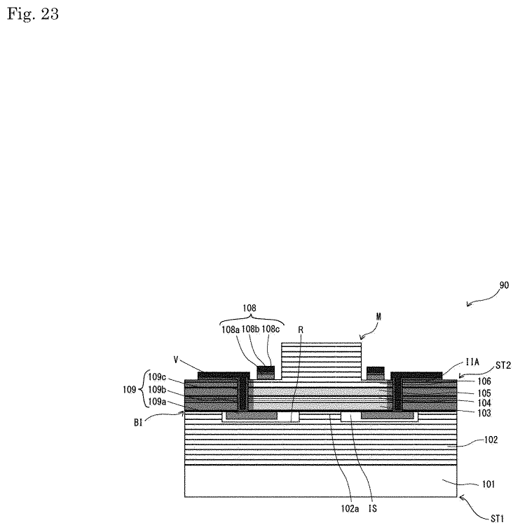

FIG. 23 is a cross-sectional view of a surface-emitting laser 90 according to Example 9 of one embodiment of the present technique.

### <<Configuration of Surface-Emitting Laser>>

As illustrated in FIG. 23, the surface-emitting laser 90 according to Example 9 has generally the same configuration as the surface-emitting laser 80 according to Example 8, except that the first reflector 102 and the first cladding layer 103 are bonded, and a bonding interface BI is present between the first reflector 102 and the first cladding layer 103.

In the surface-emitting laser 90, the internal space IS is defined by the recess R formed in the junction surface of the first reflector 102 with the first cladding layer 103 and the junction surface of the first cladding layer 103 with the first reflector 102. The recess R is formed around the central part 102a of the first reflector 102. In the surface-emitting laser 90, the cathode electrode 109a is provided on the bottom surface of the first cladding layer 103 (the surface opposite from the side on which the active layer 104 is located). The thickness of the cathode electrode 109a is preferably no greater than the depth of the recess R.

### <<Operations of Surface-Emitting Laser>>

The surface-emitting laser 90 performs generally the same operations as the surface-emitting laser 10 according to Example 1.

### <<Method for Manufacturing Surface-Emitting Laser>>

The surface-emitting laser 90 can be manufactured through a manufacturing method based on the method for manufacturing the surface-emitting laser 30 according to Example 3.

### <<Effects of Surface-Emitting Laser>>

According to the surface-emitting laser 90, the same effects as the surface-emitting laser 80 according to Example 8 can be achieved.

### <10. Surface-Emitting Laser According to Example 10 of One Embodiment of Present Technique>

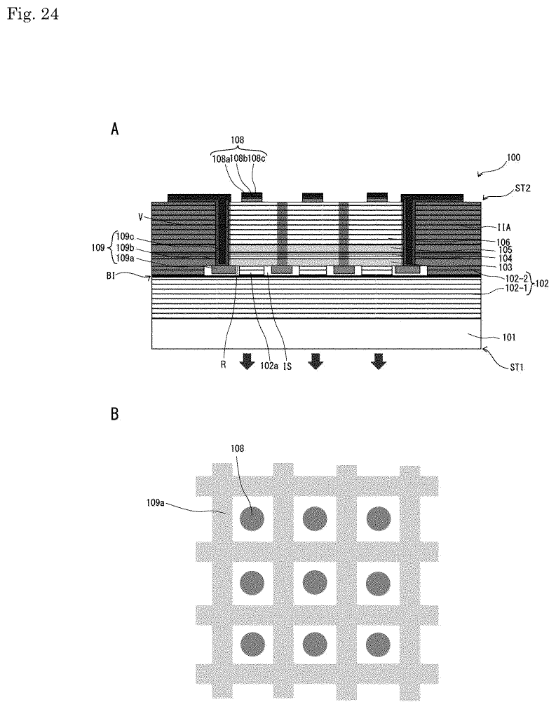

FIG. 24A is a cross-sectional view of a surface-emitting laser 100 according to Example 10 of one embodiment of the present technique. FIG. 24B is a diagram illustrating the planar layout of the anode electrode 108 and the cathode electrode 109a of the surface-emitting laser 100.

### <<Configuration of Surface-Emitting Laser>>

As illustrated in FIG. 24A and FIG. 24B, the surface-emitting laser 100 according to Example 10 has generally the same configuration as the surface-emitting laser 10 according to Example 1, except that a surface-emitting laser array is configured.

In the surface-emitting laser 100, the ion implantation region IIA serving as the current confinement region has a plurality of annular light-emitting region setting parts, and the internal space IS has a plurality of surrounding parts corresponding to the plurality of light-emitting regions. In the surface-emitting laser 100, a plurality of light-emitting regions are set in the active layer 104 by the plurality of light-emitting region setting parts of the ion implantation region IIA.

The plurality of surrounding parts of the internal space IS communicate with each other, and the cathode electrode 109a is provided in each surrounding part. The cathode electrodes 109a provided in the plurality of surrounding parts of the internal space IS are electrically connected to each other (see FIG. 24B).

In the surface-emitting laser 100, a plurality of anode electrodes 108 corresponding to the plurality of cathode electrodes 109a are provided on the second reflector 106. The plurality of anode electrodes 108 are inhibited from being conductive with each other by the ion implantation region IIA. In the surface-emitting laser 100, current can be injected into the light-emitting regions all at once or individually, and light-emitting units including the light-emitting regions can be driven all at once or individually.

### <<Operations of Surface-Emitting Laser>>

In the surface-emitting laser 100, each light-emitting unit performs generally the same operations as the surface-emitting laser 10 according to Example 1.

### <<Method for Manufacturing Surface-Emitting Laser>>

The surface-emitting laser 100 can be manufactured through a manufacturing method based on the method for manufacturing the surface-emitting laser 10 according to Example 1.

### <<Effects of Surface-Emitting Laser>>

According to the surface-emitting laser 100, it is possible to provide a narrow-pitch surface-emitting laser array that does not require the formation of a mesa and that can reduce series resistance.

### <11. Surface-Emitting Laser According to Example 11 of One Embodiment of Present Technique>

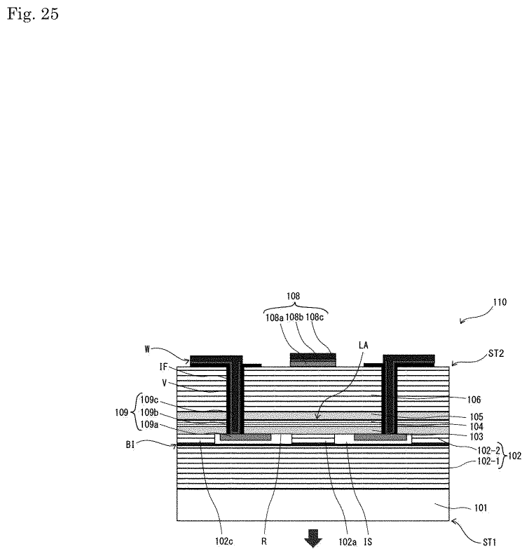

FIG. 25 is a cross-sectional view of a surface-emitting laser 110 according to Example 11 of one embodiment of the present technique.

### <<Configuration of Surface-Emitting Laser>>

As illustrated in FIG. 25, the surface-emitting laser 110 according to Example 11 has the same configuration as the surface-emitting laser 10 according to Example 1, except that an insulating film IF is provided instead of the ion implantation region IIA.

In the surface-emitting laser 110, the insulating film IF is formed on the side surface of the via V and the upper surface of the second reflector 106, and a penetrating part of the wiring W is surrounded by the insulating film IF. The insulating film IF also functions as a current confinement region.

The insulating film IF is constituted by a dielectric such as SiO₂, SiN, SiON, or the like, for example. The insulating film IF is 10 to 300 nm thick, for example.

### <<Operations of Surface-Emitting Laser>>

The surface-emitting laser 110 performs generally the same operations as the surface-emitting laser 10 according to Example 1.

### <<Method for Manufacturing Surface-Emitting Laser>>

The surface-emitting laser 110 can be manufactured through a manufacturing method based on the method for manufacturing the surface-emitting laser 10 according to Example 1.

### <<Effects of Surface-Emitting Laser>>

According to the surface-emitting laser 110, generally the same effects as the surface-emitting laser 10 according to Example 1 can be achieved.

### <12. Surface-Emitting Laser According to Example 12 of One Embodiment of Present Technique>

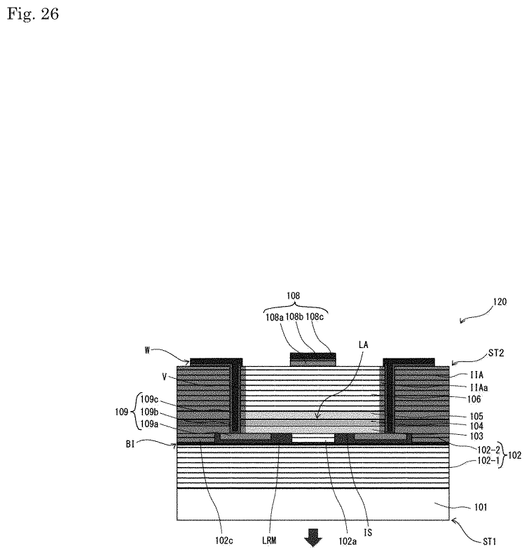

FIG. 26 is a cross-sectional view of a surface-emitting laser 120 according to Example 12 of one embodiment of the present technique.

### <<Configuration of Surface-Emitting Laser>>

As illustrated in FIG. 26, the surface-emitting laser 120 according to Example 12 has the same configuration as the surface-emitting laser 10 according to Example 1, except that a low refractive index material LRM is provided over the entire periphery of the cathode electrode 109a in the internal space IS.

The low refractive index material LRM may be a material having a lower refractive index than a semiconductor region surrounded by the low refractive index material LRM, such as SiO₂, SiN, SiON, AlN, a metal, or the like, for example.

### <<Operations of Surface-Emitting Laser>>

The surface-emitting laser 120 performs generally the same operations as the surface-emitting laser 10 according to Example 1.

### <<Method for Manufacturing Surface-Emitting Laser>>

The surface-emitting laser 120 can be manufactured through a manufacturing method based on the method for manufacturing the surface-emitting laser 10 according to Example 1.

### <<Effects of Surface-Emitting Laser>>

According to the surface-emitting laser 120, generally the same effects as the surface-emitting laser 10 according to Example 1 can be achieved.

### <13. Variations on Internal Space of Surface-Emitting Laser According to One Embodiment of Present Technique>

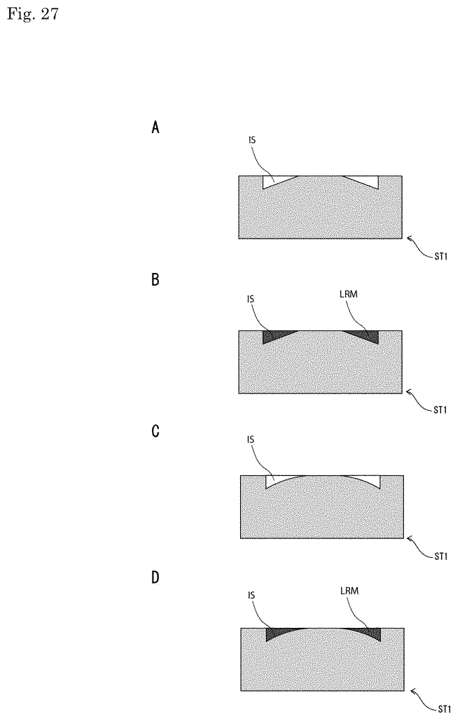

The surface-emitting laser according to one embodiment of the present technique may have a shape in which the cross-section of the surrounding part of the internal space IS becomes thinner with proximity to the center, for example, as illustrated in FIG. 27A to FIG. 27D. In FIG. 27A to FIG. 27D, the cathode electrode 109a is not illustrated for the sake of convenience.

The example in FIG. 27A has a tapered shape in which the cross-section of the surrounding part of the internal space IS becomes thinner with proximity to the center. The example in FIG. 27B has a tapered shape in which the cross-section of the surrounding part of the internal space IS becomes thinner with proximity to the center, and the low refractive index material LRM is provided in the internal space IS. The example in FIG. 27C has a shape in which the cross-section of the surrounding part of the internal space IS becomes thinner with proximity to the center, with the bottom edge having a curve. The example in FIG. 27D has a tapered shape in which the cross-section of the surrounding part of the internal space IS becomes thinner with proximity to the center, with the bottom edge having a curve, and the low refractive index material LRM is provided in the internal space IS.

### <14. Light Source Device Including Surface-Emitting Laser According to Example 1 of One Embodiment of Present Technique>

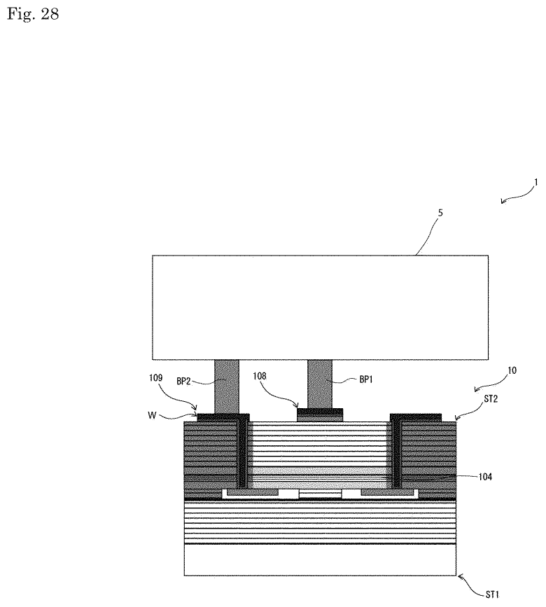

FIG. 28 is a cross-sectional view of a light source device 1 including the surface-emitting laser 10 according to Example 1 of one embodiment of the present technique.

As illustrated in FIG. 28, the light source device 1 includes the surface-emitting laser 10, and a laser driver 5 electrically connected to each of the anode electrode 108 and the cathode wiring system 109 of the surface-emitting laser 10 through conductive bumps. In other words, the surface-emitting laser 10 is flip-chip (junction-down) connected to the laser driver 5.

The anode electrode 108 and the laser driver 5 are electrically connected by a conductive bump BP1. The part of the wiring W of the cathode wiring system 109, disposed on the second structure ST2, and the laser driver 5 are electrically connected by a conductive bump BP2. The conductive bump BP1 may be attached to either the anode electrode 108 or the laser driver 5, respectively, before the surface-emitting laser 10 and the laser driver 5 are flip-chip connected. The conductive bump BP2 may be attached to either the cathode wiring system 109 or the laser driver 5 before the surface-emitting laser 10 and the laser driver 5 are flip-chip connected. Each conductive bump is, for example, a metal bump.

The anode electrode 108 is connected to an anode-side terminal of the laser driver by the conductive bump BP1, for example. The cathode wiring system 109 is connected to a cathode-side terminal of the laser driver by the conductive bump BP2, for example.

The laser driver 5 includes a driver IC, for example, and is mounted on a printed circuit board. The driver IC has an NMOS driver that controls the voltage applied to the surface-emitting laser 10, for example.

### <15. Light Source Device Including Surface-Emitting Laser According to Example 10 of One Embodiment of Present Technique>

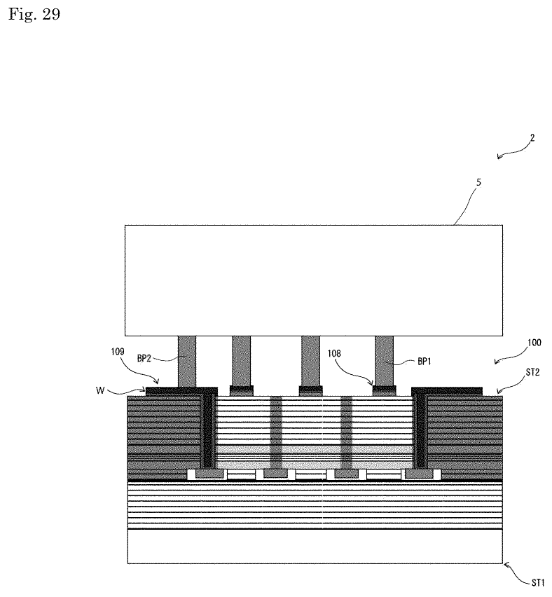

FIG. 29 is a cross-sectional view of a light source device 2 including the surface-emitting laser 100 according to Example 10 of one embodiment of the present technique.

As illustrated in FIG. 29, the light source device 2 includes the surface-emitting laser 100, and a laser driver 5 electrically connected to each of a plurality of the anode electrodes 108 and the cathode wiring system 109 of the surface-emitting laser 100 through conductive bumps. In other words, the surface-emitting laser 100 is flip-chip (junction-down) connected to the laser driver 5.

Each anode electrode 108 and the laser driver 5 are electrically connected by a conductive bump BP1. The part of the wiring W of the cathode wiring system 109, disposed on the second structure ST2, and the laser driver 5 are electrically connected by a conductive bump BP2. The conductive bump BP1 may be attached to either the anode electrode 108 or the laser driver 5 before the surface-emitting laser 100 and the laser driver 5 are flip-chip connected. The conductive bump BP2 may be attached to either the cathode wiring system 109 or the laser driver 5 before the surface-emitting laser 100 and the laser driver 5 are flip-chip connected. Each conductive bump is, for example, a metal bump.

The plurality of the anode electrodes 108 are connected individually to a plurality of anode-side terminals of the laser driver by the conductive bump BP1, for example. The cathode wiring system 109 is connected to a cathode-side terminal of the laser driver by the conductive bump BP2, for example.

### <16. Other Variations on Present Technique>

The present technique is not limited to the foregoing examples and variations, and can be varied in other ways as well.

For example, the cathode electrode may be provided in an annular shape (e.g., a ring shape) to surround the central part of the semiconductor layer (the light transmissive region) in the internal space IS. In this case, it is preferable that the inner diameter of the cathode electrode be about 1 to 200 μm longer than the outer diameter of the central part of the semiconductor layer, and that the outer diameter of the cathode electrode be about 1 to 200 μm shorter than the inner diameter of the peripheral part of the semiconductor layer.

For example, the current confinement in the surface-emitting laser is not limited to the ion implantation region. For example, the current may be confined a through QWI, embedded tunnel junction, or the like, which traps carrier by providing a band gap energy difference between inside and outside the aperture due to Ga vacancy diffusion.

For example, the substrate 101 may be a Si substrate, a GaN substrate, an InP substrate, or the like. In any of these cases, it is preferable that the semiconductor layer layered on the substrate 101 be selected as appropriate to match the lattice of the material of the substrate 100. Any material having an oscillation wavelength in the 200 to 2000 nm wavelength band can be used for the surface-emitting laser.

The first and second reflectors 102 and 106 are not limited to semiconductors, and may, for example, be constituted by one type, or a combination of two or more types, selected from semiconductors, dielectrics, and metals.

The anode electrode 108 and/or the cathode wiring system 109 may not have either the pad metal or the plating metal. For example, the plating metal may be omitted, or the pad metal may be omitted. Metal of other materials (such as Cu) may be layered on the plating metal. The anode electrode 108 and/or the cathode wiring system 109 may have a transparent conductive film. For example, the cathode electrode 109a may be constituted by a transparent conductive film.

In the method for manufacturing the surface-emitting laser, of the via V and the wiring W, at least the via V may be formed in the second layered body L2 before bonding the first and second layered bodies L1 and L2.

In the method of manufacturing the surface-emitting laser, the cathode electrode 109a may be provided at a position corresponding to the recess R in the one of the first and second layered bodies L1 and L2 in which the recess R is not formed.

A contact layer in contact with anode electrode 108 and/or the cathode electrode 109a may be provided.

The shape of the light-emitting unit when seen in plan view is not limited to a circular shape, and can be, for example, polygonal, oval, or the like.

The conductivity types (n type and p type) of the first and second structures ST1 and ST2 of the surface-emitting laser in the foregoing examples and variations may be swapped.

Some of the configurations of the surface-emitting lasers in the foregoing examples and variations may be combined as long as they do not conflict with each other.

In each of the examples and variations described above, the material, conductivity type, thickness, width, numerical value, shape, size, and the like of each layer constituting the surface-emitting laser can be changed as needed within a scope in which the function as a surface-emitting laser is maintained.

### <17. Example of Application to Electronic Device>

The technique according to the present disclosure (the present technique) can be applied in various products (electronic devices). For example, the technique according to the present disclosure may be realized as a device mounted on any type of moving body such as an automobile, an electric automobile, a hybrid electric automobile, a motorcycle, a bicycle, a personal mobility device, an airplane, a drone, a ship, a robot, or the like.

The surface-emitting laser according to the present technique can be applied, for example, as a light source for a device that forms or displays images using laser light (e.g., laser printers, laser copiers, projectors, head-mounted displays, heads-up displays, and the like).

### <18. Example of Applying Surface-Emitting Laser to Distance Measurement Device>

An example of the application of the surface-emitting laser according to the foregoing embodiment and variations will be described hereinafter.

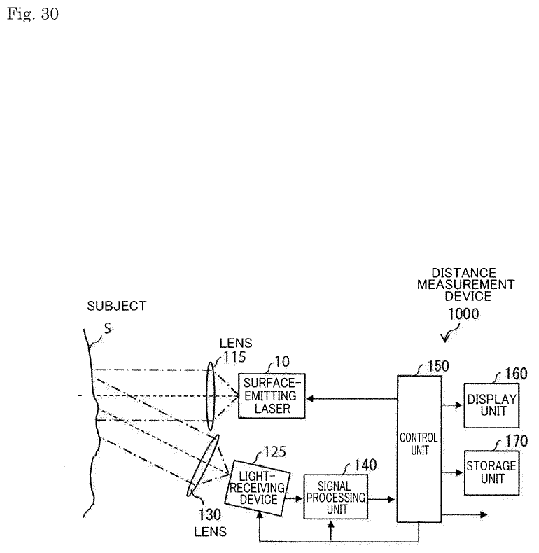

FIG. 30 illustrates an example of the overall configuration of a distance measurement device 1000 including the surface-emitting laser 10 as an example of an electronic device according to the present technique. The distance measurement device 1000 measures the distance to a subject S using the Time Of Flight (TOF) method. The distance measurement device 1000 includes the surface-emitting laser 10 as a light source. The distance measurement device 1000 includes, for example, the surface-emitting laser 10, a light-receiving device 125, lenses 115 and 130, a signal processing unit 140, a control unit 150, a display unit 160, and a storage unit 170.

The light-receiving device 125 detects light reflected by the subject S. The lens 115 is a lens for converting light emitted from the surface-emitting laser 10 into parallel light, and is a collimate lens. The lens 130 is a lens for focusing light reflected by the subject S and guiding that light to the light-receiving device 125, and is a focusing lens.

The signal processing unit 140 is a circuit for generating a signal corresponding to a difference between a signal input from the light-receiving device 125 and a reference signal input from the control unit 150. The control unit 150 is configured including a Time to Digital Converter (TDC), for example. The reference signal may be a signal input from the control unit 150, or may be an output signal from a detection unit that directly detects the output of the surface-emitting laser 10. The control unit 150 is, for example, a processor that controls the surface-emitting laser 10, the light-receiving device 125, the signal processing unit 140, the display unit 160, and the storage unit 170. The control unit 150 is a circuit that measures the distance to the subject S based on the signal generated by the signal processing unit 140. The control unit 150 generates an image signal for displaying information about the distance to the subject S, and outputs the image signal to the display unit 160. The display unit 160 displays the information about the distance to the subject S based on the image signal input from the control unit 150. The control unit 150 stores the information about the distance to the subject S in the storage unit 170.

In the present application example, any of the foregoing surface-emitting lasers 20, 30, 40, 40, 50, 60, 70, 80, 90, 100, 110, and 120 can be applied in the distance measurement device 1000 instead of the surface-emitting laser 10.

### <19. Example of Installing Distance Measurement Device on Moving Body>

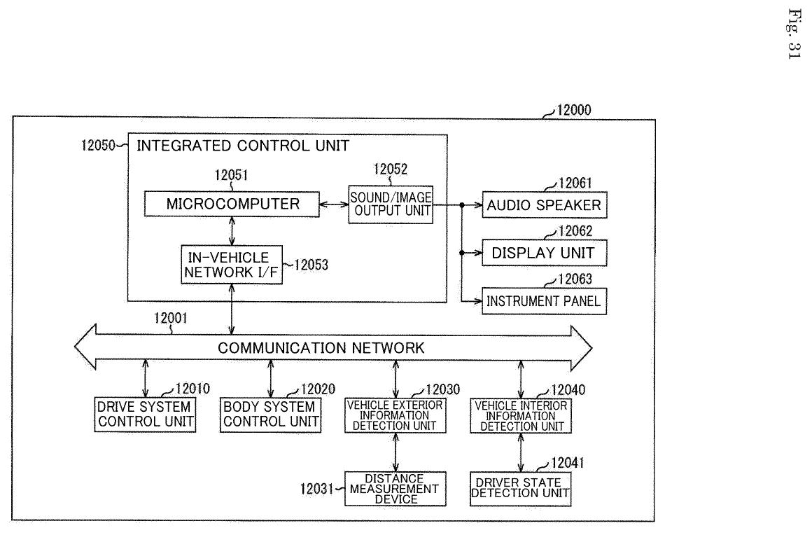

FIG. 31 is a block diagram schematically illustrating an example of the configuration of a vehicle control system, which is an example of a moving body control system to which the technique according to the present disclosure can be applied.

A vehicle control system 12000 includes a plurality of electronic control units connected over a communication network 12001. In the example illustrated in FIG. 31, the vehicle control system 12000 includes a drive system control unit 12010, a body system control unit 12020, a vehicle exterior information detection unit 12030, a vehicle interior information detection unit 12040, and an integrated control unit 12050. In addition, a microcomputer 12051, a sound/image output unit 12052, and an in-vehicle network interface (I/F) 12053 are illustrated as functional configurations of the integrated control unit 12050.

The drive system control unit 12010 controls operations of devices related to a drive system of the vehicle according to various types of programs. For example, the drive system control unit 12010 functions as control devices, such as a driving force generation device for generating driving force for the vehicle, such as an internal combustion engine or a driving motor; a driving force transmission mechanism for transmitting driving force to wheels; a steering mechanism for adjusting a turning angle of the vehicle; a braking device that generates braking force for the vehicle; and the like.

The body system control unit 12020 controls operations of various devices mounted in the vehicle body according to various programs. For example, the body system control unit 12020 functions as control devices for a keyless entry system, a smart key system, power window devices, or various lamps such as headlights, backup lights, brake lights, turn signals, fog lights, and the like. In this case, radio waves emitted from a portable device that substitutes for a key or signals from various switches can be input to the body system control unit 12020. The body system control unit 12020 receives the input of the radio waves or signals and controls door lock devices, power window devices, the lamps, and the like of the vehicle.

The vehicle exterior information detection unit 12030 detects information on the exterior of the vehicle in which the vehicle control system 12000 is installed. For example, a distance measurement device 12031 is connected to the vehicle exterior information detection unit 12030. The distance measurement device 12031 includes the distance measurement device 1000 described above. The vehicle exterior information detection unit 12030 causes the distance measurement device 12031 to measure the distance to an object (the subject S) outside the vehicle and obtains distance data obtained as a result. The vehicle exterior information detection unit 12030 may perform object detection processing for people, cars, obstacles, signs, and the like based on the obtained distance data.

The vehicle interior information detection unit 12040 detects information on the interior of the vehicle. For example, a driver state detection unit 12041 that detects a state of a driver is connected to the vehicle interior information detection unit 12040. The driver state detection unit 12041 includes, for example, a camera that captures an image of the driver, and the vehicle interior information detection unit 12040 may calculate the level of the driver's fatigue or concentration, or may determine whether the driver is dozing, based on detection information input from the driver state detection unit 12041.

For example, the microcomputer 12051 can calculate control target values for the driving force generation device, the steering mechanism, or the braking device based on information on the inside and outside of the vehicle obtained by the vehicle exterior information detection unit 12030 and the vehicle interior information detection unit 12040, and output control commands to the drive system control unit 12010. For example, the microcomputer 12051 can perform coordinated control for the purpose of implementing functions of an Advanced Driver Assistance System (ADAS) including vehicle collision avoidance, impact mitigation, following traveling based on an inter-vehicle distance, constant vehicle speed driving, vehicle collision warnings, and lane departure warnings.

Additionally, the microcomputer 12051 can perform coordinated control for the purpose of automated driving or the like in which autonomous travel is performed without requiring operations of the driver, by controlling the driving force generation device, the steering mechanism, the braking device, or the like based on information about the surroundings of the vehicle, the information being obtained by the vehicle exterior information detection unit 12030 or the vehicle interior information detection unit 12040.

In addition, the microcomputer 12051 can output control commands to the body system control unit 12020 based on the information on the exterior of the vehicle obtained by the vehicle exterior information detection unit 12030. For example, the microcomputer 12051 can perform coordinated control for the purpose of suppressing glare, such as switching from high beams to low beams by controlling the headlights according to the position of a preceding vehicle or an oncoming vehicle detected by the vehicle exterior information detection unit 12030.

The sound/image output unit 12052 transmits an output signal of at least one of sound and an image to an output device capable of visually or audibly providing information to an occupant or to the exterior of the vehicle. In the example illustrated in FIG. 31, an audio speaker 12061, a display unit 12062, and an instrument panel 12063 are illustrated as examples of the output device. The display unit 12062 may include at least one of an on-board display and a heads-up display, for example.

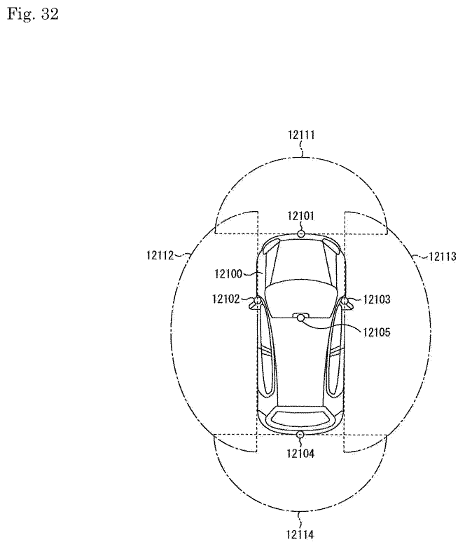

FIG. 32 is a diagram illustrating an example of an installation positions of the distance measurement device 12031.

In FIG. 32, a vehicle 12100 has distance measurement devices 12101, 12102, 12103, 12104, and 12105 as the distance measurement device 12031.

The distance measurement devices 12101, 12102, 12103, 12104, and 12105 are provided at the positions of the front nose, the side-view mirrors, the rear bumper, the trunk door, an upper part of the windshield within the vehicle cabin, and the like of the vehicle 12100, for example. The distance measurement device 12101 provided on the front nose and the distance measurement device 12105 provided in an upper part of the windshield within the vehicle cabin mainly obtain data from in front of the vehicle 12100. The distance measurement devices 12102 and 12103 provided in the side-view mirrors mainly obtain data from the sides of the vehicle 12100. The distance measurement device 12104 provided on the rear bumper or the trunk door mainly obtains data of an area behind the vehicle 12100. The data obtained by the distance measurement devices 12101 and 12105 is mainly used for detecting preceding vehicles, pedestrians, obstacles, traffic signals, traffic signs, and the like.

FIG. 32 illustrates an example of detection ranges of the distance measurement devices 12101 to 12104. A detection range 12111 indicates a detection range of the distance measurement device 12101 provided on the front nose; detection ranges 12112 and 12113 respectively indicate the detection ranges of the distance measurement devices 12102 and 12103 provided in the side-view mirrors; and a detection range 12114 indicates the detection range of the distance measurement device 12104 provided on the rear bumper or the trunk door.

For example, the microcomputer 12051 can extract, particularly, a closest three-dimensional object on a path through which the vehicle 12100 is traveling, which is a three-dimensional object traveling at a predetermined speed (for example, at least 0 km/h) in substantially the same direction as the vehicle 12100, as a preceding vehicle by obtaining a distance to each three-dimensional object in the detection ranges 12111 to 12114 and temporal changes in the distance (a relative speed with respect to the vehicle 12100) based on the distance data obtained from the distance measurement devices 12101 to 12104. The microcomputer 12051 can also set an inter-vehicle distance to the preceding vehicle to be maintained in advance and perform automatic brake control (including following stop control) and automatic acceleration control (including following start control). It is therefore possible to perform coordinated control for the purpose of, for example, automated driving in which the vehicle travels in an automated manner without requiring the driver to perform operations.

For example, the microcomputer 12051 can classify and extract three-dimensional data regarding three-dimensional objects as two-wheeled vehicles, normal vehicles, large vehicles, pedestrians, and other three-dimensional objects such as electrical poles based on the distance data obtained from the distance measurement devices 12101 to 12104, and can use the three-dimensional data to automatically avoid obstacles. For example, the microcomputer 12051 classifies obstacles around the vehicle 12100 into obstacles visible to the driver of the vehicle 12100 and obstacles which are difficult to see. Then, the microcomputer 12051 determines a collision risk indicating the degree of risk of collision with each obstacle, and when the collision risk is at least a set value and there is a possibility of a collision, an alarm is output to the driver through the audio speaker 12061 or the display unit 12062, forced deceleration or avoidance steering is performed through the drive system control unit 12010, and the like, making it possible to provide driving assistance for collision avoidance.

An example of the moving body control system to which the technique according to the present disclosure can be applied has been described thus far. The technique according to the present disclosure may be applied in the distance measurement device 12031 and the like among the above-described configurations.

In addition, the present technique can also have the following configurations.
(1) A surface-emitting laser including:
a first structure including a first reflector;
a second structure including a second reflector; and
an active layer disposed between the first and second structures,
wherein an electrode is provided within the first structure.
(2) The surface-emitting laser according to (1),
wherein the first structure has an internal space, and the electrode is provided within the internal space.
(3) The surface-emitting laser according to (2),
wherein the electrode is provided in a wall surface of the internal space.
(4) The surface-emitting laser according to (2) or (3),
wherein a current confinement region having at least one annular light-emitting region setting part that sets a light-emitting region of the active layer is formed in the first structure and/or the second structure, and
the internal space has a surrounding part, in which the electrode is disposed, that surrounds a part of the first structure corresponding to a central part of the light-emitting region.
(5) The surface-emitting laser according to (4),
wherein the electrode includes a plurality of electrode parts disposed at different positions in the surrounding part.
(6) The surface-emitting laser according to any one of (2) to (5), further including: a wiring provided so as to penetrate the second structure, the active layer, and a part between the internal space of the first structure and the active layer, with one end of the wiring being connected to the electrode.
(7) The surface-emitting laser according to (6),
wherein the penetrating part of the wiring is surrounded by a high-resistance region or an insulating region.
(8) The surface-emitting laser according to (6) or (7),
wherein an other end of the wiring is disposed on a surface of the second structure opposite from the active layer side.
(9) The surface-emitting laser according to any one of (4) to (8),
wherein the at least one light-emitting region setting part is a plurality of light-emitting region setting parts; and
the internal space has a plurality of the peripheral parts each corresponding to one of a plurality of the light-emitting regions.
(10) The surface-emitting laser according to (9),
wherein the plurality of the electrodes provided in the plurality of the surrounding parts are electrically connected to each other.
(11) The surface-emitting laser according to any one of (2) to (10),
wherein a low refractive index material is provided in a region of the internal space that surrounds the electrode.
(12) The surface-emitting laser according to any one of (2) to (11),
wherein in the first structure, a first component part including at least a part of the first reflector and a second component part are overlaid and bonded together, and
a first junction surface that is a junction surface of one of the first and second component parts with the other of the first and second component parts includes a wall surface of the internal space.
(13) The surface-emitting laser according to (12),
wherein the internal space is defined by: a recess provided in a second junction surface that is a junction surface of the other of the first and second component parts with the one of the first and second component parts; and the first junction surface.
(14) The surface-emitting laser according to any one of (4) to (13),
wherein a cross-section of the surrounding part has a shape that becomes thinner with proximity to a center.
(15) The surface-emitting laser according to any one of (3) to (14),
wherein the first structure includes a semiconductor layer having the wall surface on the active layer side.
(16) The surface-emitting laser according to (4),
wherein an other electrode is provided in a region surrounded by the light-emitting region setting part when seen in plan view, on a surface of the second structure opposite from the active layer side.
(17) The surface-emitting laser according to (16),
wherein the other electrode has a surrounding part surrounding a center of the light-emitting region when seen in plan view.
(18) The surface-emitting laser according to (16) or (17),
wherein the second structure has a mesa including at least a part of the second reflector, and the other electrode is located in a region of the second structure in a periphery of the mesa.
(19) The present technique provides a light source device including: the surface-emitting laser according to any one of (8) to (18); and
a laser driver that drives the surface-emitting laser,
wherein the laser driver and the other end of the wiring are bonded by a conductive bump.
(20) An electronic device including:
the surface-emitting laser according to any one of (1) to (19).

### REFERENCE SIGNS LIST

10, 20, 30, 40, 50, 60, 70, 80, 90, 100, 110, 120 Surface-emitting laser
101 Substrate
102 First reflector
103 First cladding layer (semiconductor layer)
104 Active layer
106 Second reflector
108 Anode electrode (other electrode)
109a Cathode electrode
109a1, 109a2 Electrode part
ST1 First structure
ST2 Second structure
IS Internal space
ISa Surrounding part
R Recess
LA Light-emitting region
JS1 Junction surface
JS2 Junction surface
W Wiring
IIA Ion implantation region (current confinement region)
IIAa Light-emitting region setting part
LRM Low refractive index material
BP1, BP2 Conductive bump
1000 Distance measurement device (electronic device)

1. A surface-emitting laser comprising:
a first structure including a first reflector;
a second structure including a second reflector; and
an active layer disposed between the first and second structures,
wherein an electrode is provided within the first structure.

2. The surface-emitting laser according to claim 1,
wherein the first structure has an internal space, and
the electrode is provided within the internal space.

3. The surface-emitting laser according to claim 2,
wherein the electrode is in contact with a wall surface of the internal space.

4. The surface-emitting laser according to claim 2,
wherein a current confinement region having at least one annular light-emitting region setting part that sets a light-emitting region of the active layer is formed in the first structure and/or the second structure, and
the internal space has a surrounding part, in which the electrode is disposed, that surrounds a part of the first structure corresponding to a central part of the light-emitting region.

5. The surface-emitting laser according to claim 4,
wherein the electrode includes a plurality of electrode parts disposed at different positions in the surrounding part.

6. The surface-emitting laser according to claim 2, further comprising:
a wiring provided so as to penetrate the second structure, the active layer, and a part between the internal space of the first structure and the active layer, with one end of the wiring being connected to the electrode.

7. The surface-emitting laser according to claim 6,
wherein a penetrating part of the wiring is surrounded by a high-resistance region or an insulating region.

8. The surface-emitting laser according to claim 6,
wherein an other end of the wiring is disposed on a surface of the second structure opposite from the active layer side.

9. The surface-emitting laser according to claim 4,
wherein the at least one light-emitting region setting part is a plurality of light-emitting region setting parts; and
the internal space has a plurality of the surrounding parts each corresponding to one of a plurality of the light-emitting regions.

10. The surface-emitting laser according to claim 9,
wherein the plurality of the electrodes provided in the plurality of the surrounding parts are electrically connected to each other.

11. The surface-emitting laser according to claim 2,
wherein a low refractive index material is provided in a region of the internal space that surrounds the electrode.

12. The surface-emitting laser according to claim 2,
wherein in the first structure, a first component part including at least a part of the first reflector and a second component part are overlaid and bonded together, and
a first junction surface that is a junction surface of one of the first and second component parts with the other of the first and second component parts includes the wall surface of the internal space.

13. The surface-emitting laser according to claim 12,
wherein the internal space is defined by: a recess provided in a second junction surface that is a junction surface of the other of the first and second component parts with the one of the first and second component parts; and the first junction surface.

14. The surface-emitting laser according to claim 4,
wherein a cross-section of the surrounding part has a shape that becomes thinner with proximity to a center.

15. The surface-emitting laser according to claim 3,
wherein the first structure includes a semiconductor layer having the wall surface on the active layer side.

16. The surface-emitting laser according to claim 4,
wherein an other electrode is provided in a region surrounded by the light-emitting region setting part when seen in plan view, on a surface of the second structure opposite from the active layer side.

17. The surface-emitting laser according to claim 16,
wherein the other electrode has a surrounding portion surrounding a center of the light-emitting region when seen in plan view.

18. The surface-emitting laser according to claim 16,
wherein the second structure has a mesa including at least a part of the second reflector, and
the other electrode is located in a region of the second structure in a periphery of the mesa.

19. A light source device comprising:
the surface-emitting laser according to claim 8; and
a laser driver that drives the surface-emitting laser,
wherein the laser driver and the other end of the wiring are bonded by a conductive bump.

20. An electronic device comprising:
the surface-emitting laser according to claim 1.
